(19) United States
(12) Patent Application Publication
(10) Pub. No.: US 2025/0255124 A1
(43) Pub. Date: Aug. 7, 2025

(54) TRANSPARENT DISPLAY APPARATUS

(71) Applicant: LG Display Co., Ltd., Seoul (KR)

(72) Inventors: JiHun SONG, Paju-si (KR); Hoiyong KWON, Paju-si (KR)

(21) Appl. No.: 18/941,970

(22) Filed: Nov. 8, 2024

(30) Foreign Application Priority Data
Feb. 2, 2024 (KR) 10-2024-0016937

(51) Int. Cl. H10K 59/131; H10K 59/38; H10K 59/88; H10K 102/00

(52) U.S. Cl. CPC H10K 59/131; H10K 59/38; H10K 59/88; H10K 2102/3031

(57) ABSTRACT

A transparent display apparatus is provided. The transparent display apparatus includes a substrate including a non-transmissive area including a light emission area in which a light emitting element is disposed and a transmissive area. The transparent display apparatus includes at least one power line extended in a first direction in the non-transmissive area on the substrate. The transparent display apparatus includes at least one gate line extended in a second direction transverse to the first direction to cross the non-transmissive area and the transmissive area on the substrate. The transparent display apparatus includes at least one protruded line extended in different directions to cross between the first direction and the second direction on the substrate.

### CROSS-REFERENCE TO RELATED APPLICATION

This application claims priority to Korean Patent Application No. 10-2024-0016937 filed in the Republic of Korea on Feb. 2, 2024, the entire contents of which is hereby expressly incorporated by reference into the present application.

### BACKGROUND

### Technical Field

The present disclosure relates to a transparent display apparatus.

### Description of the Related Art

With the advancement of the information age, the demand for a display apparatus for displaying an image has increased in various forms. Therefore, various types of display apparatuses such as a liquid crystal display (LCD) apparatus, an organic light emitting display (OLED) apparatus, a micro light emitting diode (LED) display apparatus and a quantum dot display (QD) apparatus have been recently used.

Recently, studies for a transparent display apparatus that displays an image for a user and allows the user to view objects or images, which are positioned at an opposite side thereof, by transmitting light are actively ongoing. The transparent display apparatus includes a display area, on which an image is displayed and a non-display area, wherein the display area may include a transmissive area capable of transmitting external light and a non-transmissive area. The transparent display apparatus may have high light transmittance in the display area through the transmissive area. Such a transparent display apparatus may include a plurality of touch sensors and a plurality of touch sensor lines to implement a touch function.

### BRIEF SUMMARY

A transparent display apparatus is highly likely to be used in various fields in that a user can view images and backgrounds together. However, since the transparent display apparatus may be applied to various fields and used for various purposes, it is beneficial to be manufactured in multiple types (e.g., various sizes or various shapes). However, when the transparent display apparatus is manufactured in multiple types (various sizes or various shapes), technical problems occur in that manufacturing cost and production energy are increased due to an increase in the number of processes. The present disclosure has been made in view of the various technical problems in the related art, including the above-identified problems.

Various embodiments of the present disclosure provide a transparent display apparatus in which a cathode contact portion is provided in a simplified structure and a visibility deviation may be resolved.

Various embodiments of the present disclosure provide a transparent display apparatus that may reduce occurrence of a defect caused by moisture permeation.

Various embodiments of the present disclosure provide a transparent display apparatus that may be manufactured in multiple types (or various sizes or various shapes).

The technical benefits of the present disclosure are not limited to the aforesaid, but other benefits not described herein will be clearly understood by those skilled in the art from descriptions below.

In accordance with an aspect of the present disclosure, the above and other objects may be accomplished by the provision of a transparent display apparatus comprising a substrate including a non-transmissive area including a light emission area in which a light emitting element is disposed and a transmissive area, at least one power line extended in a first direction in the non-transmissive area on the substrate, at least one gate line extended in a second direction crossing the first direction to cross the non-transmissive area and the transmissive area on the substrate, and at least one protruded line extended in different directions to cross between the first direction and the second direction on the substrate.

According to one or more embodiments of the present disclosure, the transparent display apparatus, in which the cathode contact portion is provided in a simplified structure and a visibility deviation may be improved, may be provided.

According to one or more embodiments of the present disclosure, the transparent display apparatus, which is capable of reducing occurrence of a defect caused by moisture permeation, may be provided.

According to one or more embodiments of the present disclosure, the transparent display apparatus, which may be manufactured in multiple types (or various sizes or various shapes), may be provided.

According to one or more embodiments of the present disclosure, as the transparent display panel manufactured in a large area may be manufactured in multiple types (or various sizes or various shapes) by a cutting process, a manufacturing process for producing multiple types of transparent display apparatus may be reduced, whereby greenhouse gas that may occur due to the manufacturing process may be reduced, and thus Environment/Social/Governance (ESG) may be implemented.

The effects of the present disclosure are not limited to the aforesaid, but other effects not described herein will be clearly understood by those skilled in the art from descriptions below.

The details of the present disclosure described in technical problem, technical solution, and advantageous effects do not specify essential features of claims, and thus, the scope of claims is not limited by the details described in detailed description of the disclosure.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 is a view illustrating a transparent display apparatus according to the embodiment of the present disclosure.

FIG. 2 is a circuit view illustrating a subpixel of a transparent display apparatus according to the embodiment of the present disclosure.

FIG. 3 is a view illustrating an area A shown in FIG. 1 according to the embodiment of the present disclosure.

FIG. 4 is a view illustrating an area B shown in FIG. 3 according to the embodiment of the present disclosure.

FIG. 5 is a cross-sectional view taken along line I-I′ shown in FIG. 4 according to the embodiment of the present disclosure.

FIG. 6 is a cross-sectional view taken along line II-II′ shown in FIG. 4 according to one embodiment of the present disclosure.

FIG. 7 is a cross-sectional view taken along line III-III′ shown in FIG. 4 according to another embodiment of the present disclosure.

FIG. 8 is another cross-sectional view taken along line I-I′ shown in FIG. 4 according to the embodiment of the present disclosure.

FIG. 9 is another cross-sectional view taken along line II-II′ shown in FIG. 4 according to the embodiment of the present disclosure.

FIG. 10 is another cross-sectional view taken along line III-III′ shown in FIG. 4 according to the embodiment of the present disclosure.

FIG. 11 is another cross-sectional view taken along line I-I′ shown in FIG. 4 according to the embodiment of the present disclosure.

FIG. 12 is another cross-sectional view taken along line II-II′ shown in FIG. 4 according to the embodiment of the present disclosure.

FIG. 13 is another cross-sectional view taken along line III-III′ shown in FIG. 4 according to the embodiment of the present disclosure.

FIG. 14 is a view illustrating an area B shown in FIG. 3 according to another embodiment of the present disclosure.

FIG. 15 is a cross-sectional view taken along line IV-IV′ shown in FIG. 14 according to another embodiment of the present disclosure.

FIG. 16 is a cross-sectional view taken along line V-V′ shown in FIG. 14 according to another embodiment of the present disclosure.

FIG. 17 is another cross-sectional view taken along line IV-IV′ shown in FIG. 14 according to another embodiment of the present disclosure.

FIG. 18 is another cross-sectional view taken along line V-V′ shown in FIG. 14 according to another embodiment of the present disclosure.

FIG. 19 is a cross-sectional view illustrating a transparent display apparatus according to another embodiment of the present disclosure.

FIG. 20 is a view illustrating an area C shown in FIG. 19 according to another embodiment of the present disclosure.

FIG. 21 is a view illustrating a transparent display apparatus according to another embodiment of the present disclosure.

Throughout the drawings and the detailed description, unless otherwise described, the same drawing reference numerals should be understood to refer to the same elements, features, and structures.

### DETAILED DESCRIPTION

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete, to assist those skilled in the art to understand the inventive concepts without limiting the protected scope of the present disclosure.

Shapes (e.g., sizes, lengths, widths, heights, thicknesses, locations, radii, diameters, and areas), sizes, ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “contain,” “constitute,” “made of,” “formed of,” or the like is used with respect to one or more elements, one or more other elements may be added unless a term such as “only” or the like is used. The terms used in the present disclosure are merely used in order to describe example embodiments, and are not intended to limit the scope of the present disclosure. The terms of a singular form may include plural forms unless the context clearly indicates otherwise.

In construing an element, the element is construed as including an error region although there is no explicit description thereof.

In describing a positional relationship, for example, when the positional order is described as “on,” “above,” “below,” “beneath,” and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element is “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The term “at least one” should be understood as including any and all combinations of one or more of the associated listed items. For example, “at least one among a first element, a second element and a third element” may include all combinations of two or more elements selected from the first, second and third elements as well as each element of the first, second and third elements.

The text “at least one of A or B” should be understood to mean “only A, only B, or both A and B.”

Features of various embodiments of the present disclosure may be partially or entirety coupled to or combined with each other, may be technically associated with each other, and may be variously inter-operated, linked or driven together. The embodiments of the present disclosure may be implemented or carried out independently of each other, or may be implemented or carried out together in a co-dependent or related relationship. In one or more aspects, the components of each apparatus according to various embodiments of the present disclosure are operatively coupled and configured.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

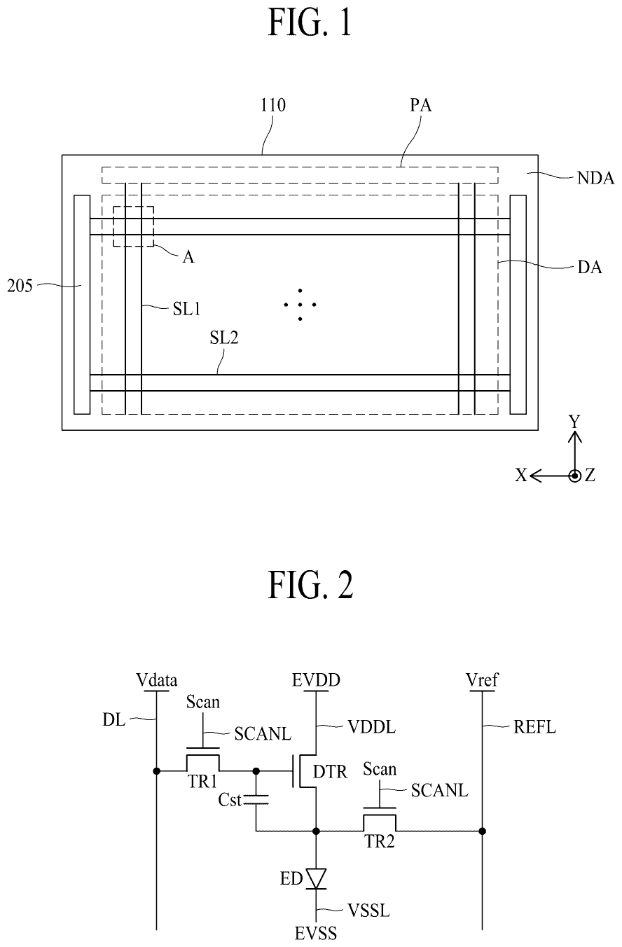

FIG. 1 is a view illustrating a transparent display apparatus according to the embodiment of the present disclosure. FIG. 2 is a circuit view illustrating a subpixel of a transparent display apparatus according to the embodiment of the present disclosure.

Hereinafter, X-axis represents a direction parallel with a scan line, Y-axis represents a direction parallel with a data line and Z-axis represents a height direction of the transparent display apparatus.

Although the transparent display apparatus according to one embodiment of the present disclosure will be described to be implemented as an organic light emitting display (OLED), it may be also implemented as a liquid crystal display (LCD), a micro LED display, a quantum dot display (QD), etc.

Referring to FIGS. 1 and 2, the transparent display apparatus according to one embodiment of the present disclosure may include a transparent display panel 110 that includes a display area DA in which pixels are configured to display an image and a non-display area NDA in which an image is not displayed.

The display area DA of the transparent display panel 110 may include first signal lines SL1, second signal lines SL2 and pixels and the non-display area NDA thereof may include a pad area PA in which pads are disposed and at least one gate driver 205.

The first signal lines SL1 may be extended in a first direction (or Y-axis direction) and may cross the second signal lines SL2 in the display area DA. The second signal lines SL2 may be extended in a second direction (or X-axis direction). The pixels may be disposed in an area where the first signal line SL1 and the second signal line SL2 cross each other and may emit predetermined light to display an image.

The gate driver 205 may be connected to a scan line to supply a scan signal. The gate driver 205 may be implemented in a gate driver in panel (GIP) method or a tape automated bonding (TAB) method on the non-display area NDA outside one side or both sides of the display area DA of the transparent display panel 110.

A source drive integrated circuit, a circuit board or a timing controller, which is connected through a flexible circuit film, may be electrically connected to the pad area PA of the transparent display panel 110.

Referring to FIG. 2, each of the pixels includes a plurality of subpixels constituting a unit pixel and each of the subpixels includes a circuit element having a 3T1C structure (three transistors and one capacitor) that includes a first switching transistor TR1, a second switching transistor TR2, a driving transistor DTR and a capacitor Cst and a light emitting element ED, but is not limited thereto. Each subpixel may further include a compensation circuit and in this case, may have various structures such as 4T2C, 5T2C, 6TIC, 6T2C, 7TIC and 7T2C.

Each of the transistors DTR, TR1 and TR2 of each subpixel may include a gate electrode, a source electrode and a drain electrode. Since the source electrode and the drain electrode are not fixed and may be changed depending on a current direction and a voltage applied to the gate electrode, one of the source electrode and the drain electrode may be expressed as a first electrode and the other one may be expressed as a second electrode. The transistors DTR, TR1 and TR2 of each subpixel may use at least one of a polysilicon semiconductor, an amorphous silicon semiconductor or an oxide semiconductor. The transistors DTR, TR1 and TR2 may be P-type or N-type transistors or P-type and N-type transistors may be used interchangeably.

The first switching transistor TR1 may serve to supply a data voltage Vdata supplied from a data line DL to the driving transistor DTR. For example, the first switching transistor TR1 may charge the capacitor Cst with the data voltage Vdata supplied from the data line DL. To this end, the gate electrode of the first switching transistor TR1 may be connected to a scan line SCANL (or a gate line) and a first electrode thereof may be connected to the data line DL. Also, a second electrode of the first switching transistor TR1 may be connected to one end of the capacitor Cst and the gate electrode of the driving transistor DTR.

The first switching transistor TR1 may be turned on in response to a scan signal Scan applied through the scan line SCANL (or the gate line). When the first switching transistor TR1 is turned on, the data voltage Vdata applied through the data line DL may be transferred to one end of the capacitor Cst.

The second switching transistor TR2 may serve to supply a reference voltage Vref supplied from a reference line REFL to the driving transistor DTR. For example, the gate electrode of the second switching transistor TR2 may be connected to the scan line SCANL (or the gate line) and a first electrode thereof may be connected to the reference line REFL. Also, the second electrode of the second switching transistor TR2 may be connected to a second electrode of the driving transistor DTR and the other end of the capacitor Cst.

The second switching transistor TR2 may be turned on in response to the scan signal Scan applied through the scan line SCANL (or the gate line). When the second switching transistor TR2 is turned on, the reference voltage Vref applied through the reference line REFL may be transferred to the other end of the capacitor Cst. Also, the reference voltage Vref may be applied to the source electrode of the driving transistor DTR.

The capacitor Cst may serve to maintain the data voltage Vdata supplied to the driving transistor DTR for one frame. For example, a first electrode of the capacitor Cst may be connected to the gate electrode of the driving transistor DTR, and a second electrode thereof may be connected to the source electrode of the driving transistor DTR. The capacitor Cst may store a voltage corresponding to the data voltage Vdata transferred through the first switching transistor TR1, and may turn on the driving transistor DTR with the stored voltage.

The driving transistor DTR may generate a data current from a first power source EVDD supplied from a pixel power source line VDDL (or a first power source line) to supply the generated data current to an anode electrode of the light emitting element ED. For example, the gate electrode of the driving transistor DTR may be connected to one end of the capacitor Cst, and the first electrode thereof may be connected to the pixel power source line VDDL. Also, a second electrode of the driving transistor DTR may be connected to the anode electrode of the light emitting element ED.

The light emitting element ED may include an anode electrode connected to the driving transistor DTR, a cathode electrode receiving a second power source EVSS from a common power line VSSL (or a second power line), and a light emitting layer between the anode electrode and the cathode electrode. The anode electrode is an independent electrode for each light emitting element, but the cathode electrode may be a common electrode shared by the entire light emitting elements. When a driving current is supplied from the driving transistor DTR, electrons from the cathode electrode may be injected into the light emitting layer and holes from the anode electrode may be injected into the light emitting layer, so that the light emitting element ED may allow fluorescent or phosphorescent materials to emit light through recombination of the electrons and the holes in the light emitting layer, thereby generating light of brightness proportional to a current value of the driving current.

The anode electrode of the light emitting element ED may be connected to the second electrode of the driving transistor DTR, and the cathode electrode thereof may be connected to the common power line VSSL. The light emitting element ED may emit light in response to the driving current generated by the driving transistor DTR.

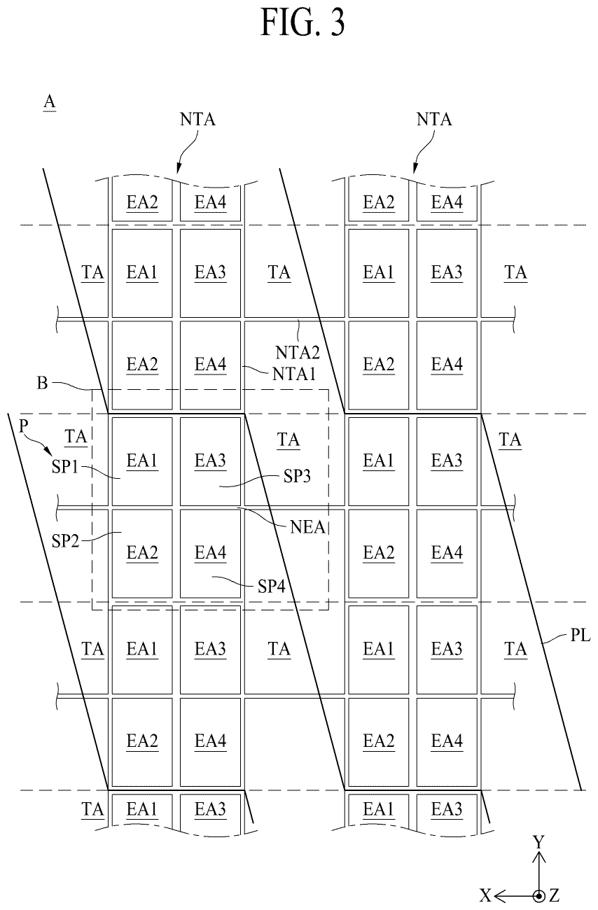

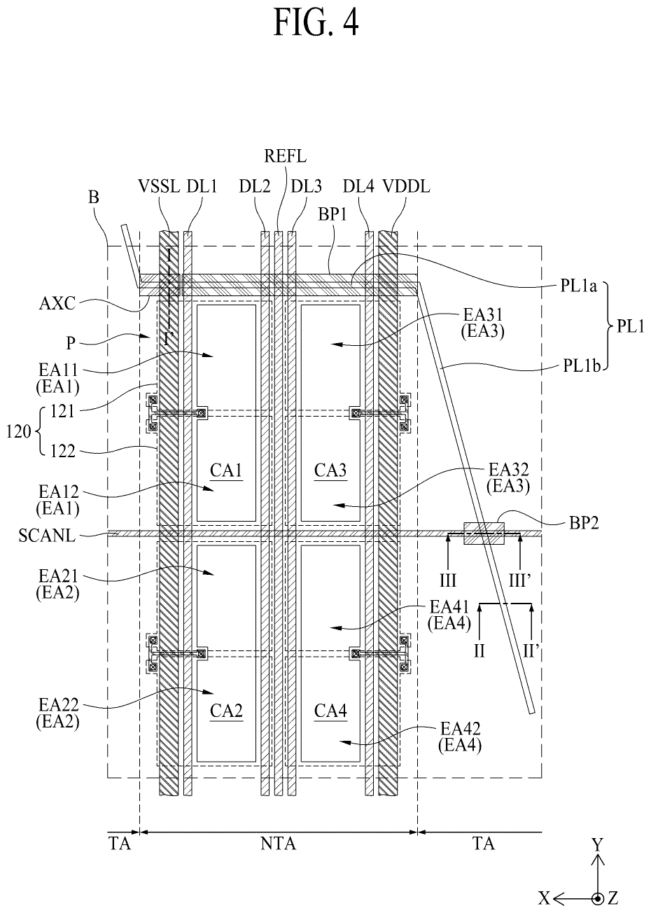

FIG. 3 is a view illustrating an area A shown in FIG. 1 according to the embodiment of the present disclosure. FIG. 4 is a view illustrating an area B shown in FIG. 3 according to the embodiment of the present disclosure.

Referring to FIGS. 3 and 4 in conjunction with FIGS. 1 and 2, the transparent display panel 110 according to the embodiment of the present disclosure may include a display area DA and a non-display area NDA. The display area DA may include a transmissive area TA and a non-transmissive area NTA. The transmissive area TA may be an area that transmits most of light incident from the outside, and the non-transmissive area NTA may be an area that does not transmit most of light incident from the outside. For example, the transmissive area TA may be an area having light transmittance greater than α% and the non-transmissive area NTA may be an area having light transmittance smaller than β%. In this case, a may be a value greater than β. A user may see an object or a background, which is positioned on a back surface (or a rear surface) of the transparent display panel 110, due to the transmissive areas TA.

The non-transmissive area NTA may include a first non-transmissive area NTA1, a second non-transmissive area NTA2 and pixels P.

The first non-transmissive area NTA1 is extended in the first direction (or Y-axis direction) in the display area DA and may be disposed to overlap at least a portion of light emission areas EA1, EA2, EA3 and EA4. A plurality of first non-transmissive areas NTA1 may be configured. The plurality of first non-transmissive areas NTA1 may be extended in the first direction (or Y-axis direction), and may be disposed to be spaced apart from each other in the second direction (or X-axis direction). Two adjacent first non-transmissive areas NTA1 may be disposed to be spaced apart from each other with the transmissive area TA interposed therebetween. For example, the transmissive area TA may be disposed between the two adjacent first non-transmissive areas NTA1. The first signal lines SL1 extended in the first direction (or Y-axis direction) may be disposed in the first non-transmissive area NTA1. For example, the first signal lines SL1 may be disposed to overlap the first non-transmissive area NTA1.

The first signal lines SL1 may include at least one of the pixel power line VDDL (or the first power line), the common power line VSSL (or the second power line), the reference line REFL or data lines DL1, DL2, DL3 and DL4. For example, the first signal lines SL1 may further include a touch sensor line, but the embodiments of the present disclosure are not limited thereto.

The pixel power line VDDL (or the first power line) may supply the first power source EVDD to the driving transistor DTR of each of subpixels SP1, SP2, SP3 and SP4 provided in the display area DA. The pixel power line VDDL may be disposed at a right side or a left side of the light emission areas EA1, EA2, EA3 and EA4. For example, the pixel power line VDDL may be disposed at the right side of the light emission areas EA1, EA2, EA3 and EA4, but the embodiments of the present disclosure are not limited thereto.

The common power line VSSL (or the second power line) may supply the second power source EVSS to the cathode electrode of the subpixels SP1, SP2, SP3 and SP4 provided in the display area DA. In this case, the second power source EVSS may be a common power source supplied in common to the subpixels SP1, SP2, SP3 and SP4. The common power line VSSL may be disposed at the right side or the left side of the light emission areas EA1, EA2, EA3 and EA4. For example, the common power line VSSL may be disposed at the right side of the light emission areas EA1, EA2, EA3 and EA4, but the embodiments of the present disclosure are not limited thereto.

The reference line REFL may supply an initialization voltage (or a reference voltage) to the driving transistor DTR of each of the subpixels SP1, SP2, SP3 and SP4 provided in the display area DA. For example, the reference line REFL may be disposed between the plurality of data lines DL1, DL2, DL3 and DL4. For example, the reference line REFL may be disposed in the middle of the plurality of data lines DL1, DL2, DL3 and DL4.

Each of the data lines DL1, DL2, DL3 and DL4 may supply the data voltage Vdata to each of the subpixels SP1, SP2, SP3 and SP4. For example, the first data line DL1 may supply a first data voltage to a first driving transistor of the first subpixel SP1, the second data line DL2 may supply a second data voltage to a second driving transistor of the second subpixel SP2, the third data line DL3 may supply a third data voltage to a third driving transistor of the third subpixel SP3 and the fourth data line DL4 may supply a fourth data voltage to a fourth driving transistor of the fourth subpixel SP4.

The second non-transmissive area NTA2 may be extended from the display area DA in the second direction (or X-axis direction), and may be disposed to overlap at least a portion of the light emission areas EA1, EA2, EA3 and EA4. For example, the second non-transmissive area NTA2 may be extended in the second direction (or X-axis direction) between two adjacent first non-transmissive areas NTA1. A plurality of second non-transmissive areas NTA2 may be configured. The plurality of second non-transmissive areas NTA2 may be extended in the second direction (or X-axis direction), and may be disposed to be spaced apart from each other in the first direction (or Y-axis direction). The two adjacent second non-transmissive areas NTA2 may be disposed to be spaced apart from each other with the transmissive area TA interposed therebetween. For example, the transmissive area TA may be disposed between two adjacent second non-transmissive areas NTA2. The second signal lines SL2 extended in the second direction (or X-axis direction) may be disposed in the second non-transmissive area NTA2. For example, the second signal lines SL2 may be disposed to overlap the second non-transmissive area NTA2.

The second signal lines SL2 may be extended in the second direction (or X-axis direction), and may include the scan line SCANL (or the gate line). The scan line SCANL may supply the scan signal to the subpixels SP1, SP2, SP3 and SP4 of the pixel P.

The scan line SCANL may be connected to each of the pixels P corresponding to horizontal lines disposed in parallel along the second direction (or X-axis direction). The scan line SCANL may be disposed at the center of the pixels P corresponding to the horizontal lines. For example, the scan line SCANL may be disposed between the first and third subpixels SP1 and SP3 and the second and fourth subpixels SP2 and SP4 of each pixel P. Alternatively, the scan line SCANL may be disposed above or below the pixels P corresponding to the horizontal lines. For example, the scan line SCANL may be disposed above the first and third subpixels SP1 and SP3 of the pixels P corresponding to the horizontal line, or may be disposed below the second and fourth subpixels SP2 and SP4 of the pixels corresponding to the horizontal lines, but the embodiments of the present disclosure are not limited thereto.

The pixels P may be disposed in each crossing area where the first non-transmissive area NTA1 and the second non-transmissive area NTA2 cross each other, and may emit light to display an image. Each of the pixels P is disposed between adjacent transmissive areas TA, and the pixel P may include light emission areas EA1, EA2, EA3 and EA4 in which a light emitting element is disposed to emit light. The light emission areas EA1, EA2, EA3 and EA4 may correspond to areas, which emit light, in the pixel P. Since an area of the non-transmissive area NTA is small in the transparent display panel 110, the circuit element may be disposed to overlap the light emission areas EA1, EA2, EA3 and EA4. For example, the light emission areas EA1, EA2, EA3 and EA4 may at least partially overlap circuit areas CA1, CA2, CA3 and CA4 in which the circuit element is disposed. For example, the circuit areas CA1, CA2, CA3 and CA4 may include a first circuit area CA1 in which a circuit element connected to the first subpixel SP1 is disposed, a second circuit area CA2 in which a circuit element connected to the second subpixel SP2 is disposed, a third circuit area CA3 in which a circuit element connected to the third subpixel SP3 is disposed and a fourth circuit area CA4 in which a circuit element connected to the fourth subpixel SP4 is disposed.

Each of the pixels P is provided in the first non-transmissive area NTA1, and may emit light to display an image. Each of the pixels P may include a first subpixel SP1, a second subpixel SP2, a third subpixel SP3 and a fourth subpixel SP4. The first subpixel SP1 may include a first light emission area EA1 emitting light of a first color, the second subpixel SP2 may include a second light emission area EA2 emitting light of a second color, the third subpixel SP3 may include a third light emission area EA3 emitting light of a third color and the fourth subpixel SP4 may include a fourth light emission area EA4 emitting light of a fourth color.

The first to fourth light emission areas EA1, EA2, EA3 and EA4 may emit light of different colors. For example, the first light emission area EA1 may emit green light, the second light emission area EA2 may emit blue light, the third light emission area EA3 may emit white light and the fourth light emission area EA4 may emit red light, but the embodiments of the present disclosure are not limited thereto. For example, various modifications may be made in the arrangement order or arrangement form of each of the subpixels SP1, SP2, SP3 and SP4.

The first to fourth subpixels SP1, SP2, SP3 and SP4 may be disposed in a quad-type matrix along the first direction (or Y-axis direction) and the second direction (or X-axis direction). The first to fourth subpixels SP1, SP2, SP3 and SP4 may be disposed to be adjacent to the pixel power line VDDL (or the first power line) or the common power line VSSL (or the second power line). For example, the first and second subpixels SP1 and SP2 may be disposed to be adjacent to the common power line VSSL, and the third and fourth subpixels SP3 and SP4 may be disposed to be adjacent to the pixel power line VDDL, but the embodiments of the present disclosure are not limited thereto.

Referring to FIG. 4, the transparent display panel 110 according to the embodiment of the present disclosure may include light emission areas in which the plurality of light emission areas EA1, EA2, EA3 and EA4 respectively included in the plurality of subpixels SP1, SP2, SP3 and SP4 are divided into a plurality of light emission areas. For example, each of the plurality of subpixels SP1, SP2, SP3 and SP4 may include a first divided electrode 121 and a second divided electrode 122, in which first electrodes 120 (or anode electrodes) of the light emitting element are spaced apart from each other. Each of the first divided electrode 121 and the second divided electrode 122 may correspond to the divided light emission area. For example, the first light emission area EA1 provided in the first subpixel SP1 may include a first divided light emission area EA11 and a second divided light emission area EA12, which correspond to the first divided electrode 121 and the second divided electrode 122. The second light emission area EA2 provided in the second subpixel SP2 may include a first divided light emission area EA21 and a second divided light emission area EA22, which correspond to the first divided electrode 121 and the second divided electrode 122. The third light emission area EA3 provided in the third subpixel SP3 may include a first divided light emission area EA31 and a second divided light emission area EA32, which correspond to the first divided electrode 121 and the second divided electrode 122. The fourth light emission area EA4 provided in the fourth subpixel SP4 may include a first divided light emission area EA41 and a second divided light emission area EA42, which correspond to the first divided electrode 121 and the second divided electrode 122. When particles occur in any one of the first divided electrode 121 and the second divided electrode 122 according to the embodiment of the present disclosure, the divided electrode in which particles occur may be electrically separated from or disconnected from the circuit areas CA1, CA2, CA3 and CA4, whereby the divided electrodes may be repaired so that only the divided electrode in which particles occur becomes a dark spot and the remaining divided electrode is normally operated.

The circuit areas CA1, CA2, CA3 and CA4 of the plurality of subpixels SP1, SP2, SP3 and SP4 may include a capacitor Cst, at least one thin film transistor DRT, TR1 or TR2 and a light emitting element ED, as shown in FIG. 2. For example, at least one thin film transistor DRT, TR1 or TR2 may include a driving transistor DTR, a first switching transistor TR1 and a second switching transistor TR2. Also, the light emitting element ED may include a first electrode (or an anode electrode or a pixel electrode), a light emitting layer (or an organic light emitting layer), and a second electrode (or a cathode electrode or a common electrode).

The transparent display panel 110 according to the embodiment of the present disclosure may further include at least one protruded line PL extended in different directions to cross between the first direction (or Y-axis direction) and the second direction (or X-axis direction) in the display area DA.

At least one protruded line PL may be disposed in the non-transmissive area NTA and the transmissive area TA of the display area DA. For example, at least one protruded line PL may include a portion extended in the second direction (or X-axis direction) in the non-transmissive area NTA of the display area DA and a portion extended in a third direction (or a diagonal direction) between the first direction (or Y-axis direction) and the second direction (or X-axis direction) in the transmissive area TA of the display area DA.

At least one protruded line PL may be configured to be protruded in an upward direction (or Z-axis direction) of the transparent display panel 110 (or substrate). At least one protruded line PL may include at least one of an inorganic insulating layer (e.g., a passivation layer) or an organic insulating layer (e.g., a planarization layer). At least one protruded line PL may be made of the same material as that of the planarization layer on the inorganic insulating layer (e.g., the passivation layer). For example, at least one protruded line PL may be configured in the form of a line pattern protruded in the upward direction (or Z-axis direction) of the transparent display panel 110 (or the substrate) by patterning the planarization layer. At least one protruded line PL may be configured by removing at least a portion of at least one inorganic insulating layer (e.g., the passivation layer) below the line pattern consisting of the planarization layer. For example, at least one protruded line PL may include an undercut area configured by removing at least a portion of at least one inorganic insulating layer (e.g., the passivation layer) below the line pattern consisting of the planarization layer.

The undercut area of at least one protruded line PL may serve to disconnect the light emitting layer (or the organic light emitting layer) formed in the display area DA. For example, the undercut area of at least one protruded line PL may be configured to separate or disconnect the light emitting layer (or the organic light emitting layer) formed in the non-transmissive area NTA and the transmissive area TA of the display area DA.

Referring to FIG. 4, at least one protruded line PL1 according to the embodiment of the present disclosure may include a first protruded line portion PL1a overlapped with the non-transmissive area NTA and a second protruded line portion PL1b overlapped with the transmissive area TA.

The first protruded line portion PL1a of at least one protruded line PL1 may be extended in the second direction (or X-axis direction). The first protruded line portion PL1a may be configured to be extended in the second direction (or X-axis direction) in the non-transmissive area NTA. The first protruded line portion PL1a may be configured to overlap at least a portion of at least one power line in the non-transmissive area NTA and not to overlap the scan line SCANL (or the gate line). For example, the first protruded line portion PL1a may be disposed to overlap the pixel power line VDDL (or the first power line) and the common power line VSSL (or the second power line). The first protruded line portion PL1a may be disposed in the non-transmissive area NTA so as not to overlap the scan line SCANL (or the gate line). For example, the first protruded line portions PL1a may be disposed to be spaced apart from each other with the scan line SCANL (or the gate line), which is adjacent thereto in the first direction (or Y-axis direction) and interposed therebetween, in the non-transmissive area NTA. For example, the plurality of subpixels SP1, SP2, SP3 and SP4 and the scan line SCANL (or the gate line) may be disposed between the first protruded line portions PL1a spaced apart from each other in the first direction (or Y-axis direction).

The first protruded line portion PL1a may include an undercut area configured by removing at least a portion of at least one inorganic insulating layer (e.g., the passivation layer) below the line pattern consisting of the planarization layer. The undercut area of the first protruded line portion PL1a may separate or disconnect the light emitting layer (or the organic light emitting layer) disposed in the non-transmissive area NTA between pixels P adjacent to each other in the first direction (or Y-axis direction). For example, the undercut area of the first protruded line portion PL1a may separate or disconnect the light emitting layer of the upper pixel P and the light emitting layer of the lower pixel P, which are adjacent to each other in the first direction (or Y-axis direction), from each other. Furthermore, the first protruded line portion PL1a is configured in the form of a line pattern protruded in the upward direction (or Z-axis direction) of the transparent display panel 110 (or substrate) by patterning the planarization layer, so that the planarization layer (or the organic insulating layer) of the upper pixel P and the planarization layer (or the organic insulating layer) of the lower pixel P, which are adjacent to each other in the first direction (or Y-axis direction), may be separated or disconnected from each other. Therefore, the first protruded line portion PL1a may block a moisture permeation path between the pixels P adjacent to each other in the first direction (or Y-axis direction).

Referring to FIG. 4, an auxiliary power contact portion AXC and a first block pattern BP1 may be further included in the non-transmissive area NTA overlapped with the first protruded line portion PL1a according to the embodiment of the present disclosure.

The auxiliary power contact portion AXC may be disposed in the non-transmissive area NTA, electrically connected to the common power line VSSL (or the second power line) and disposed to overlap at least a portion of the first protruded line portion PL1a. The auxiliary power contact portion AXC may be connected to the common power line VSSL to supply the second power source EVSS to the second electrode (or the cathode electrode) of the light emitting element ED. For example, the second power source EVSS may be a common power source supplied in common to the subpixels SP1, SP2, SP3 and SP4.

The auxiliary power contact portion AXC may overlap the common power line VSSL extended in the first direction (or Y-axis direction) in the non-transmissive area NTA, and may be electrically connected to the common power line VSSL through a contact hole passing through at least one insulating layer (e.g., the passivation layer) interposed therebetween and the common power line VSSL. The auxiliary power contact portion AXC may overlap at least a portion of the first protruded line portion PL1a, and a portion of the auxiliary power contact portion AXC may be exposed by the undercut area of the first protruded line portion PL1a. For example, the exposed portion of the auxiliary power contact portion AXC may be in direct contact with and electrically connected to the second electrode (or the cathode electrode) of the light emitting element ED.

At least one first signal line (e.g., a data line, a reference line or a pixel power line) extended in the first direction (or Y-axis direction) may be disposed below the first protruded line portion PL1a in the non-transmissive area NTA. The first block pattern BP1 may be disposed at a portion of the non-transmissive area NTA, where the first protruded line portion PL1a and at least one first signal line (e.g., the data line, the reference line or the pixel power line) cross and overlap each other. The first block pattern BP1 may be disposed between the first protruded line portion PL1a and at least one first signal line (e.g., the data line, the reference line or the pixel power line). For example, the first block pattern BP1 and the auxiliary power contact portion AXC may be integrally formed or spaced apart from each other. For example, the first block pattern BP1 and the auxiliary power contact portion AXC may be made of the same material on the same layer, but the embodiments of the present disclosure are not limited thereto. The first block pattern BP1 may prevent at least one first signal line (e.g., the data line, the reference line and the pixel power line) overlapped with the first protruded line portion PL1a from being damaged in the process of forming the undercut area of the first protruded line portion PL1a.

The second protruded line portion PL1b of at least one protruded line PL1 may be extended in the third direction (or the diagonal direction) between the first direction (or Y-axis direction) and the second direction (or X-axis direction). The second protruded line portion PL1b may be configured to be extended in the third direction (or the diagonal direction) in the transmissive area TA. The second protruded line portion PL1b may be configured so as not to overlap at least one power line in the transmissive area TA, but may be configured to overlap at least a portion of the scan line SCANL (or the gate line).

The second protruded line portion PL1b may include an undercut area configured by removing at least a portion of at least one inorganic insulating layer (e.g., the passivation layer) below the line pattern consisting of the planarization layer. The undercut area of the second protruded line portion PL1b may separate or disconnect the light emitting layer (or the organic light emitting layer) disposed in the transmissive area TA. For example, the undercut area of the second protruded line portion PL1b may divide the transmissive area TA in the third direction (or the diagonal direction), and may separate or disconnect the light emitting layer (or the organic light emitting layer) disposed at a left side in the third direction (or the diagonal direction) and the light emitting layer (or the organic light emitting layer) disposed at a right side in the third direction (or the diagonal direction) from each other. Furthermore, the second protruded line portion PL1b may be configured in the form of a line pattern protruded in the upward direction (or Z-axis direction) of the transparent display panel 110 (or substrate) by patterning the planarization layer, so that the planarization layer (or the organic insulating layer) disposed at the left side and the planarization layer (or the organic insulating layer) disposed at the right side with respect to the third direction (or the diagonal direction) in the transmissive area TA may be separated or disconnected from each other. Therefore, the second protruded line portion PL1b may configure a boundary line that divides and disconnects the transmissive area TA in the third direction (or the diagonal direction), and may block the moisture permeation path between the divided transmissive areas TA.

Referring to FIG. 4, a second block pattern BP2 may be further included in the transmissive area TA that overlaps the second protruded line portion PL1b according to the embodiment of the present disclosure.

At least one scan line SCANL (or the gate line) extended in the second direction (or X-axis direction) may be disposed below the second protruded line portion PL1b in the transmissive area TA. The second block pattern BP2 may be disposed at a portion in the transmissive area TA, where the second protruded line portion PL1b and at least one scan line SCANL (or the gate line) overlap each other. The second block pattern BP2 may be disposed between the second protruded line portion PL1b and at least one scan line SCANL (or the gate line). The second block pattern BP2 may prevent at least one scan line SCANL (or the gate line) overlapped with the second protruded line portion PL1b from being damaged in the process of forming the undercut area of the second protruded line portion PL1b.

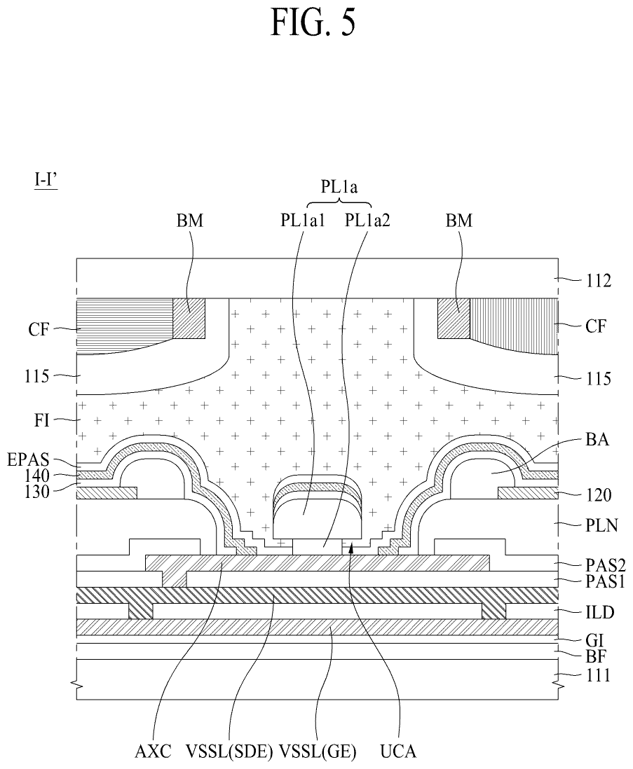

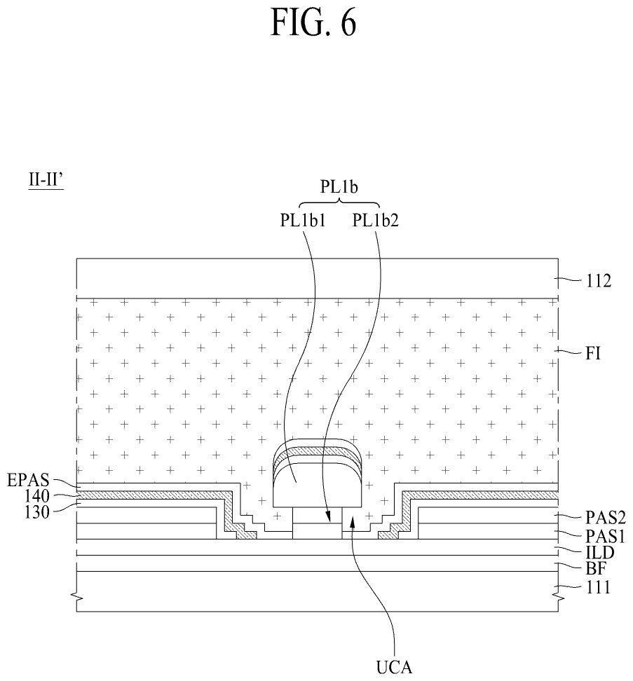

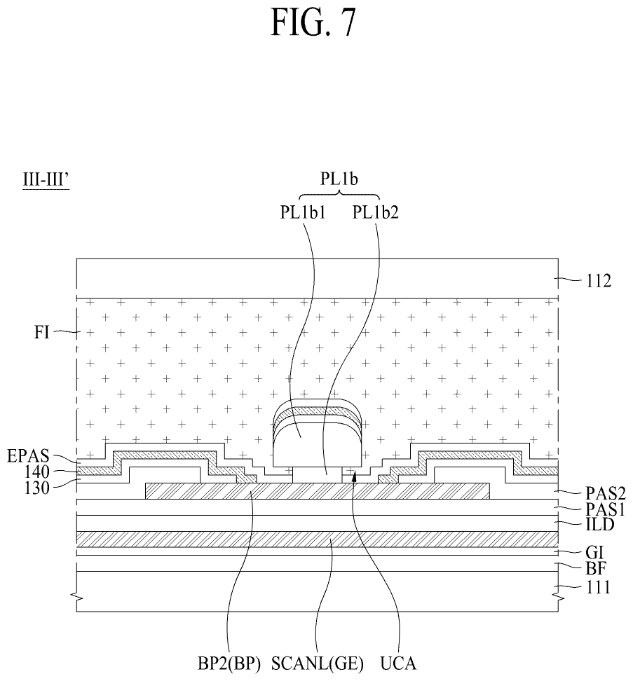

FIG. 5 is a cross-sectional view taken along line I-I′ shown in FIG. 4 according to the embodiment of the present disclosure. FIG. 6 is a cross-sectional view taken along line II-II′ shown in FIG. 4 according to one embodiment of the present disclosure. FIG. 7 is a cross-sectional view taken along line III-III′ shown in FIG. 4 according to another embodiment of the present disclosure.

Referring to FIGS. 5 to 7 in conjunction with FIG. 4, the substrate 111 of the transparent display panel 110 according to the embodiment of the present disclosure may include a non-transmissive area NTA including the light emission area EA, and a transmissive area TA. At least one protruded line PL1 extended in different directions to cross between the first direction (or Y-axis direction) and the second direction (or X-axis direction) may be included on the substrate 111. At least one protruded line PL1 on the substrate 111 may include a first protruded line portion PL1a overlapped with the non-transmissive area NTA and a second protruded line portion PL1b overlapped with the transmissive area TA.

Referring to FIG. 5, the first protruded line portion PL1a of at least one protruded line PL1 may be disposed in the non-transmissive area NTA on the substrate 111. The first protruded line portion PL1a may be extended in the second direction (or X-axis direction) in the non-transmissive area NTA. The first protruded line portion PL1a may be disposed to overlap the common power line VSSL (or the second power line) in the non-transmissive area NTA.

A buffer layer BF may be disposed on the substrate 111, and at least one insulating layer, a thin film transistor and at least one signal line may be disposed on the buffer layer BF. For example, the common power line VSSL may be disposed on the buffer layer BF. The common power line VSSL may include at least one metal layer. For example, the common power line VSSL may include a first common power line VSSL(GE) and a second common power line VSSL(SDE), which are disposed on different layers. For example, the first common power line VSSL(GE) may be made of the same material on the same layer as the gate electrode GE of the thin film transistor. A gate insulating layer GI may be disposed between the first common power line VSSL(GE) and the buffer layer BF. Also, the second common power line VSSL(SDE) may be made of the same material on the same layer as a source/drain electrode SDE of the thin film transistor. An interlayer insulating layer ILD may be disposed between the first common power line VSSL(GE) and the second common power line VSSL(SDE). The first common power line VSSL(GE) and the second common power line VSSL(SDE) may be electrically connected to each other through a contact hole passing through the interlayer insulating layer ILD.

A first passivation layer PAS1 may be disposed on the interlayer insulating layer ILD on which the second common power line VSSL(SDE) of the common power line VSSL is disposed. A second passivation layer PAS2 may be disposed on the first passivation layer PAS1. The first passivation layer PAS1 and the second passivation layer PAS2 may be formed of a single layer or multi-layer, which includes an inorganic insulating material such as silicon oxide (SiOx), silicon nitride (SiNx) or aluminum oxide (Al₂O₃).

The auxiliary power contact portion AXC may be disposed on the first passivation layer PAS1. The auxiliary power contact portion AXC may be disposed to overlap the common power line VSSL. The auxiliary power contact portion AXC may be electrically connected to the second common power line VSSL(SDE) of the common power line VSSL through a contact hole passing through the first passivation layer PAS1.

A planarization layer PLN for planarizing a step difference caused by a thin film transistor and a plurality of signal lines may be disposed on the second passivation layer PAS2 and the auxiliary power contact portion AXC. The planarization layer PLN may be formed of an organic material such as an acrylic resin, an epoxy resin, a phenolic resin, a polyamide resin and a polyimide resin.

Light emitting elements, which consist of a first electrode 120, an organic light emitting layer 130 and a second electrode 140, and a bank layer BA may be disposed on the planarization layer PLN.

The first electrode 120 may be disposed for each of the subpixels SP1, SP2, SP3 and SP4, and may be disposed in the non-transmissive area NTA. The first electrode 120 may be formed of a metal material having high reflectance, such as a stacked structure (Ti/Al/Ti) of aluminum and titanium, a stacked structure (ITO/Al/ITO) of aluminum and ITO, Ag alloy, a stacked structure (ITO/Ag alloy/ITO) of Ag alloy and ITO, MoTi alloy, and a stacked structure (ITO/MoTi alloy/ITO) of MoTi alloy and ITO. The Ag alloy may be an alloy of silver (Ag), palladium (Pd), copper (Cu) and the like. The MoTi alloy may be an alloy of molybdenum (Mo) and titanium (Ti). The first electrode 120 may be an anode electrode of the light emitting element. The organic light emitting layer 130 and the second electrode 140 may be disposed on the first electrode 120. The first electrode 120, the organic light emitting layer 130 and the second electrode 140 may constitute the light emitting element.

The bank layer BA may be disposed on the planarization layer PLN. The bank layer BA may be disposed between the first electrodes 120. For example, the bank layer BA may be configured to cover an edge of each of the first electrodes 120 and expose a portion of each of the first electrodes 120. The bank layer BA may be formed of an organic layer such as an acrylic resin, an epoxy resin, a phenolic resin, a polyamide resin and a polyimide resin.

The organic light emitting layer 130 may be disposed on the first electrode 120. The organic light emitting layer 130 may include a hole transporting layer, an emission material layer and an electron transporting layer. For example, when a voltage is applied to the first electrode 120 and the second electrode 140, holes and electrons move to the organic light emitting layer 130 through the hole transporting layer and the electron transporting layer, respectively, and may be combined with each other in the light emitting layer to emit light. The organic light emitting layer 130 may be separated or disconnected by the undercut area UCA of at least one protruded line PL1. For example, the organic light emitting layer 130 may be separated or disconnected by the undercut area UCA of the first protruded line portion PL1a of at least one protruded line PL1.

The second electrode 140 may be a common layer commonly formed in the subpixels SP1, SP2, SP3 and SP4 to apply the same voltage. The second electrode 140 may be formed of a transparent conductive material (TCO) such as ITO or IZO capable of transmitting light or a semi-transmissive conductive material such as magnesium (Mg), silver (Ag) or an alloy of magnesium (Mg) and silver (Ag). When the second electrode 140 is formed of a semi-transmissive metal material, light emission efficiency may be increased by a micro cavity. The second electrode 140 may be a cathode electrode of the light emitting element.

An encapsulation layer EPAS may be disposed on the light emitting elements. The encapsulation layer EPAS may be configured to cover the second electrode 140 on the second electrode 140. The encapsulation layer EPAS may serve to prevent oxygen or moisture from being permeated into the organic light emitting layer 130 and the second electrode 140. For example, the encapsulation layer EPAS may include at least one inorganic layer, and may further include at least one organic layer, but the embodiments of the present disclosure are not limited thereto.

The first protruded line portion PL1a of at least one protruded line PL1 may be configured using the planarization layer PLN and the second passivation layer PAS2. For example, the first protruded line portion PL1a may be configured by removing at least a portion of the planarization layer PLN and the second passivation layer PAS2. The first protruded line portion PL1a may include a first pattern line PL1a1 made of the same material as that of the planarization layer PLN, and a second pattern line PL1a2 supporting the first pattern line PL1a1, configured by removing at least a portion of the second passivation layer PAS2 to have the undercut area UCA below the first pattern line PL1a1.

The first protruded line portion PL1a may be disposed on a portion of the auxiliary power contact portion AXC. The first protruded line portion PL1a may be configured to expose a portion of the auxiliary power contact portion AXC. For example, a portion of the auxiliary power contact portion AXC may be exposed by the undercut area UCA of the first protruded line portion PL1a. The exposed portion of the auxiliary power contact portion AXC may be electrically connected to the second electrode 140 (or the cathode electrode) of the light emitting element in contact with the second electrode 140.

A color filter CF may be disposed on an opposite substrate 112 disposed to face the substrate 111. The color filter CF may be configured by being patterned for each of the subpixels SP1, SP2, SP3 and SP4. For example, the color filter CF may include a first color filter, a second color filter, a third color filter and a fourth color filter. Each of the first to fourth color filters may be made of an organic material that transmits light of different colors.

A black matrix BM may be disposed between the color filters CF and between the color filters CF and the transmissive area TA. The black matrix BM may be disposed between the subpixels SP1, SP2, SP3 and SP4, may prevent color mixture from occurring between the adjacent subpixels SP1, SP2, SP3 and SP4, and may prevent light incident from the outside from being reflected in the plurality of signal lines disposed between the subpixels SP1, SP2, SP3 and SP4. For example, the plurality of signal lines may include a scan line SCANL, a data line DL, a pixel power line VDDL, a common power line VSSL, a reference line REFL and the like.

The black matrix BM may be disposed between the transmissive area TA and the plurality of subpixels SP1, SP2, SP3 and SP4 to prevent light emitted from each of the plurality of subpixels SP1, SP2, SP3 and SP4 from moving to the transmissive area TA. For example, the black matrix BM may include a material that absorbs light, for example, a black dye that absorbs all of light in a visible wavelength band.

The color filter CF and the black matrix BM may not be disposed in the transmissive area TA to maintain high light transmittance in the transmissive area TA.

The opposite substrate 112 may further include a plurality of upper passivation layers 115 covering the color filter CF and the black matrix BM.

The plurality of upper passivation layers 115 may be disposed to be spaced apart from each other with the transmissive area TA of the display area DA, which is interposed therebetween. The plurality of upper passivation layers 115 may be configured to cover the color filter CF. For example, the plurality of upper passivation layers 115 may be configured to cover a plurality of color filters CF. Also, the plurality of upper passivation layers 115 may be configured to cover the plurality of color filters CF and the black matrix BM. For example, the plurality of upper passivation layers 115 may be formed of an organic material.

In the transparent display panel 110 according to the embodiment of the present disclosure, the upper passivation layers 115 on the opposite substrate 112 may be disposed to be spaced apart from each other along with at least one protruded line PL1 that separates or disconnects the organic light emitting layer 130 on the substrate 111, whereby the moisture permeation path through the opposite substrate 112 may be blocked.

A connection member FI may be disposed between the substrate 111 on which the light emitting elements are disposed and the opposite substrate 112 on which the color filter CF and the black matrix BM are disposed. For example, the connection member FI may be a thermosetting resin or a UV curable resin, and may be made of an organic material having an adhesive property. For example, the connection member FI may include a material that absorbs hydrogen, but the embodiments of the present disclosure are not limited thereto.

Referring to FIGS. 6 and 7, the second protruded line portion PL1b of at least one protruded line PL1 may be disposed in the transmissive area TA on the substrate 111. The second protruded line portion PL1b may be extended in the third direction (or the diagonal direction) between the first direction (or Y-axis direction) and the second direction (or X-axis direction) in the transmissive area TA. At least a portion of the second protruded line portion PL1b may be disposed to overlap at least one scan line SCANL (or gate line) in the transmissive area TA. According to one embodiment of the present disclosure, most of the planarization layer PLN is removed from the transmissive area TA on the substrate 111 and the planarization layer is formed only in a partial area, whereby transparency of the transmissive area TA may be increased.

The buffer layer BF may be disposed on the substrate 111, and at least one insulating layer, the thin film transistor and at least one signal line may be disposed on the buffer layer BF. For example, as shown in FIG. 7, at least one scan line SCANL(GE) (or gate line) may be disposed on the buffer layer BF. For example, at least one scan line SCANL(GE) may be made of the same material on the same layer as the gate electrode GE of the thin film transistor. The gate insulating layer GI may be disposed between at least one scan line SCANL(GE) and the buffer layer BF.

The interlayer insulating layer ILD may be disposed on the buffer layer BF on which at least one scan line SCANL(GE) is disposed. The first passivation layer PAS1 may be disposed on the interlayer insulating layer ILD. The second passivation layer PAS2 may be disposed on the first passivation layer PAS1. The first passivation layer PAS1 and the second passivation layer PAS2 may be formed of a single layer or multi-layer, which includes an inorganic insulating material such as silicon oxide (SiOX), silicon nitride (SiNX) and aluminum oxide (Al₂O₃).

The planarization layer PLN may be disposed on the second passivation layer PAS2. The second protruded line portion PL1b of the at least one protruded line PL1 may be configured by using at least one inorganic insulating layer and the planarization layer PLN. For example, the second protruded line portion PL1b may be configured by removing at least one inorganic insulating layer (e.g., the first and second passivation layers PAS1 and PAS2) and at least a portion of the planarization layer PLN. For example, the second protruded line portion PL1b may include a first pattern line PL1b1 made of the same material as that of the planarization layer PLN, and a second pattern line PL1b2 supporting the first pattern line PL1b1, configured by removing at least a portion of the first passivation layer PAS1 and the second passivation layer PAS2 to have an undercut area UCA below the first pattern line PL1b1.

Referring to FIG. 6, the second protruded line portion PL1b may be extended along the third direction (or the diagonal direction) in the transmissive area TA, and the second protruded line portion PL1b may not overlap the scan line SCANL (or the gate line) in the transmissive area TA. The second protruded line portion PL1b that does not overlap the scan line SCANL (or the gate line) may include a first pattern line PL1b1 made of the same material as that of the planarization layer PLN and a second pattern line PL1b2 consisting of the first passivation layer PAS1 and the second passivation layer PAS2. The first pattern line PL1b1 of the second protruded line portion PL1b may be configured in the form of a line pattern protruded in the upward direction (or Z-axis direction) of the transparent display panel 110 (or the substrate) by patterning the planarization layer PLN. The second pattern line PL1b2 of the second protruded line portion PL1b may configure the undercut line UCL by removing at least portions of the first passivation layer PAS1 and the second passivation layer PAS2 below the first pattern line PL1b1. According to the embodiment of the present disclosure, the second protruded line portion PL1b includes the undercut area UCA, and the undercut area UCA of the second protruded line portion PL1b may separate or disconnect the organic light emitting layer 130 disposed in the transmissive area TA.

Referring to FIG. 7, the second protruded line portion PL1b may be extended along the third direction (or the diagonal direction) in the transmissive area TA, and the second protruded line portion PL1b may overlap the scan line SCANL (or the gate line) in the transmissive area TA. The second block pattern BP2 may be disposed at a portion where the second protruded line portion PL1b overlaps the scan line SCANL (or the gate line). The second block pattern BP2 may be disposed on the first passivation layer PAS1. For example, the second block pattern BP2 may prevent at least one scan line SCANL (or the gate line), which overlaps the second protruded line portion PL1b, from being damaged in the process of forming the undercut area UCA of the second protruded line portion PL1b.

The second protruded line portion PL1b that overlaps the scan line SCANL (or the gate line) may include a first pattern line PL1b1 made of the same material as that of the planarization layer PLN and a second pattern line PL1b2 consisting of the second passivation layer PAS2. The first pattern line PL1b1 of the second protruded line portion PL1b may be configured in the form of a line pattern protruded in the upward direction (or Z-axis direction) of the transparent display panel 110 (or the substrate) by patterning the planarization layer PLN. The second pattern line PL1b2 of the second protruded line portion PL1b may configure the undercut area UCA by removing at least a portion of the second passivation layer PAS2 below the first pattern line PL1b1. According to one embodiment of the present disclosure, the second protruded line portion PL1b includes the undercut area UCA, and the second block pattern BP2 is disposed below the undercut area UCA, whereby the scan line SCANL (or the gate line) may be prevented from being damaged by an etchant used when the undercut area UCA is formed. In addition, the undercut area UCA of the second protruded line portion PL1b may separate or disconnect the organic light emitting layer 130 disposed in the transmissive area TA.

In the transparent display panel 110 according to the embodiment of the present disclosure, at least one protruded line PL1 having an undercut area UCA may be configured to be extended in the first direction (or Y-axis direction) and the third direction (or the diagonal direction) to cross between the first direction (or Y-axis direction) and the second direction (or X-axis direction) in the display area DA, whereby a boundary line in which the organic light emitting layer 130 and the planarization layer PLN, which may be a path for moisture permeation, are continuously removed in the diagonal direction, may be formed in the display area DA. Therefore, the outside of the diagonal boundary line formed by at least one protruded line PL1 may be a cutting passible area capable of preventing moisture permeation toward the pixel P even though it is cut (or separated). As a result, in the transparent display panel 110 according to the embodiment of the present disclosure, the cutting possible area may be provided in the display area DA in the diagonal direction by at least one protruded line PL1, so that a cuttable transparent display panel, which may be manufactured by being divided into various sizes and shapes depending on the field to which the transparent display panel 110 is applied and the usage thereof, may be implemented or realized.

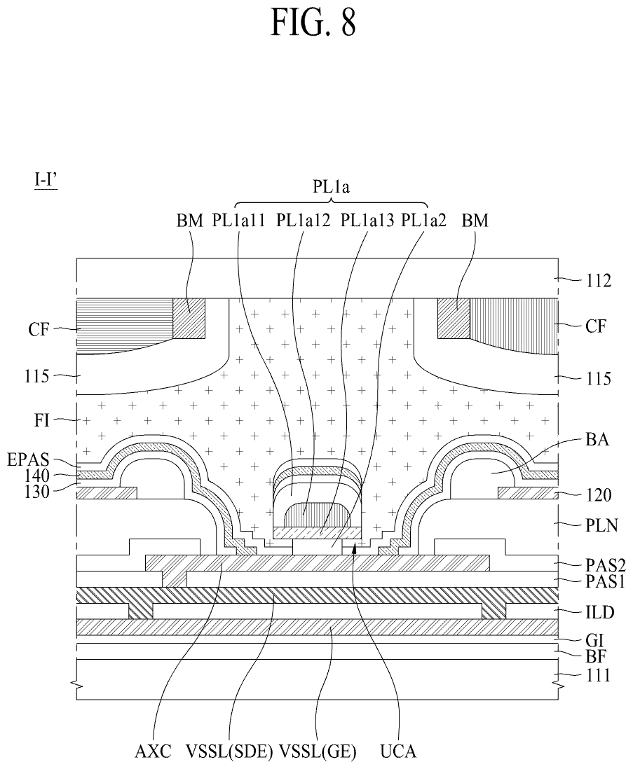

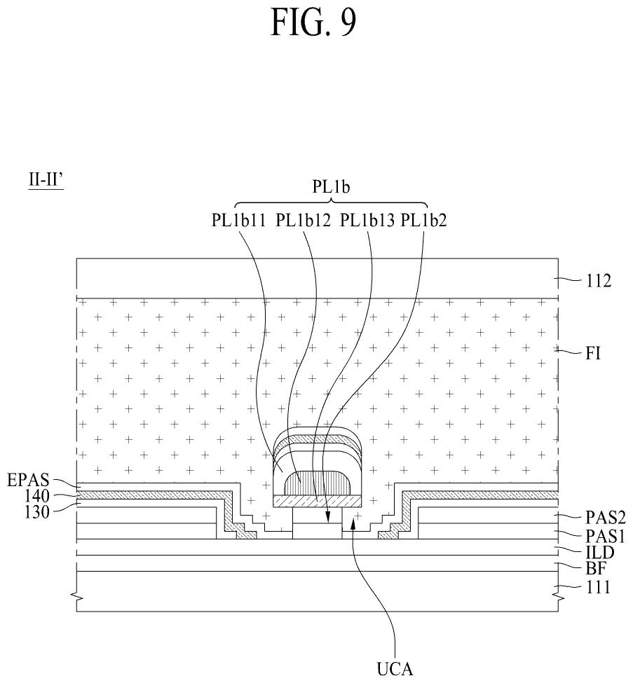

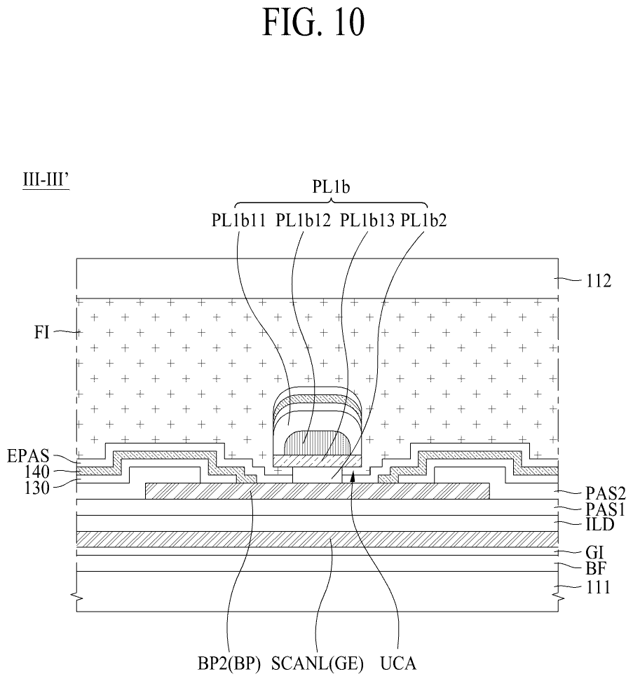

FIG. 8 is another cross-sectional view taken along line I-I′ shown in FIG. 4 according to the embodiment of the present disclosure. FIG. 9 is another cross-sectional view taken along line II-II′ shown in FIG. 4 according to the embodiment of the present disclosure. FIG. 10 is another cross-sectional view taken along line III-III′ shown in FIG. 4 according to the embodiment of the present disclosure. In FIGS. 8 to 10, the elements of at least one protruded line are modified in the transparent display panel 110 described with reference to FIGS. 1 to 7. In the following description, the same reference numerals will be given to the other same elements except for the modified elements, and their redundant description will be omitted or briefly described.

Referring to FIGS. 8 to 10 in conjunction with FIG. 4, the transparent display panel 110 according to one embodiment of the present disclosure may include at least one protruded line PL1 that includes a color filter material and a dummy electrode pattern.

At least one protruded line PL1 may be configured to be extended in different directions to cross between the first direction (or Y-axis direction) and the second direction (or X-axis direction) on the substrate 111. At least one protruded line PL1 on the substrate 111 may include a first protruded line portion PL1a overlapped with the non-transmissive area NTA and a second protruded line portion PL1b overlapped with the transmissive area TA.

Referring to FIG. 8, the first protruded line portion PL1a of at least one protruded line PL1 may be disposed in the non-transmissive area NTA on the substrate 111. The first protruded line portion PL1a may be extended in the second direction (or X-axis direction) in the non-transmissive area NTA.

The first protruded line portion PL1a of at least one protruded line PL1 may be configured using the planarization layer PLN and the second passivation layer PAS2. The first protruded line portion PL1a may further include a color filter material and a dummy electrode pattern. For example, the first protruded line portion PL1a may be configured using the planarization layer PLN, the color filter material, the dummy electrode pattern and the second passivation layer PAS2.

The first protruded line portion PL1a may include a (1-1)th pattern line PL1a11 made of the same material as that of the planarization layer PLN, a (1-2)th pattern line PL1a12 made of a color filter material, a dummy electrode pattern PL1a13 made of a metal material, and a second pattern line PL1a2 supporting the (1-1)th pattern line PL1a11, the (1-2)th pattern line PL1a12 and the dummy electrode pattern PL1a13, configured by removing at least a portion of the second passivation layer PAS2 to have an undercut area UCA below the dummy electrode pattern PL1a13.

The dummy electrode pattern PL1a13 may be disposed on the second pattern line PL1a2. The dummy electrode pattern PL1a13 may be made of a transparent conductive material. For example, the dummy electrode pattern PL1a13 may include any one of ITO and IZO, but the embodiments of the present disclosure are not limited thereto.

The (1-2)th pattern line PL1a12 made of a color filter material may be disposed on the dummy electrode pattern PL1a13. The color filter material of the (1-2)th pattern line PL1a12 may include a blue color material.

The (1-1)th pattern line PL1a11 may be disposed on the dummy electrode pattern PL1a13 on which the (1-2)th pattern line PL1a12 is disposed. The (1-1)th pattern line PL1a11 may be made of the same material as that of the planarization layer PLN. The (1-2)th pattern line PL1a12 may be covered by the dummy electrode pattern PL1a13 and the (1-1)th pattern line PL1a11. For example, the (1-2)th pattern line PL1a12 of the first protruded line portion PL1a is protected by being covered by the (1-1)th pattern line PL1a11 and the dummy electrode pattern PL1a13, thereby preventing the (1-2)th pattern line PL1a12 made of a color filter material from being damaged in the process of forming the undercut area UCA of the first protruded line portion PL1a.

The first protruded line portion PL1a may be disposed on a portion of the auxiliary power contact portion AXC. The first protruded line portion PL1a may be configured to expose a portion of the auxiliary power contact portion AXC. For example, a portion of the auxiliary power contact portion AXC may be exposed by the undercut area UCA of the first protruded line portion PL1a. The undercut area UCA of the first protruded line portion PL1a may include a lower edge of the dummy electrode pattern PL1a13 and a side of the second pattern line PL1a2.

Referring to FIGS. 9 and 10, the second protruded line portion PL1b of at least one protruded line PL1 may be disposed in the transmissive area TA on the substrate 111. The second protruded line portion PL1b may be extended in the third direction (or the diagonal direction) between the first direction (or Y-axis direction) and the second direction (or X-axis direction) in the transmissive area TA.

The second protruded line portion PL1b of at least one protruded line PL1 may be configured using at least one of the planarization layer PLN or the first and second passivation layers PAS1 and PAS2. The second protruded line portion PL1b may further include a color filter material and a dummy electrode pattern.

Referring to FIG. 9, the second protruded line portion PL1b that does not overlap the scan line SCANL (or the gate line) may be configured using the planarization layer PLN, the color filter material, the dummy electrode pattern, the first passivation layer PAS1 and the second passivation layer PAS2. For example, the second protruded line portion PL1b may include a (1-1)th pattern line PL1b11 made of the same material as that of the planarization layer PLN, a (1-2)th pattern line PL1b12 made of a color filter material, a dummy electrode pattern PL1b13 made of a metal material, and a second pattern line PL1b2 supporting the (1-1)th pattern line PL1b11, the (1-2)th pattern line PL1b12 and the dummy electrode pattern PL1b13, configured by removing at least a portion of the first and second passivation layers PAS1 and PAS2 to have an undercut area UCA below the dummy electrode pattern PL1b13.

Referring to FIG. 10, the second protruded line portion PL1b that overlaps the scan line SCANL (or the gate line) may be disposed on the second block pattern BP2. The second protruded line portion PL1b may be configured using the planarization layer PLN, the color filter material, the dummy electrode pattern and the second passivation layer PAS2. For example, the second protruded line portion PL1b may include a (1-1)th pattern line PL1b11 made of the same material as that of the planarization layer PLN, a (1-2)th pattern line PL1b12 made of a color filter material, a dummy electrode pattern PL1b13 made of a metal material, and a second pattern line PL1b2 supporting the (1-1)th pattern line PL1b11, the (1-2)th pattern line PL1b12 and the dummy electrode pattern PL1b13, configured by removing at least a portion of the second passivation layer PAS2 to have an undercut area UCA below the dummy electrode pattern PL1b13.

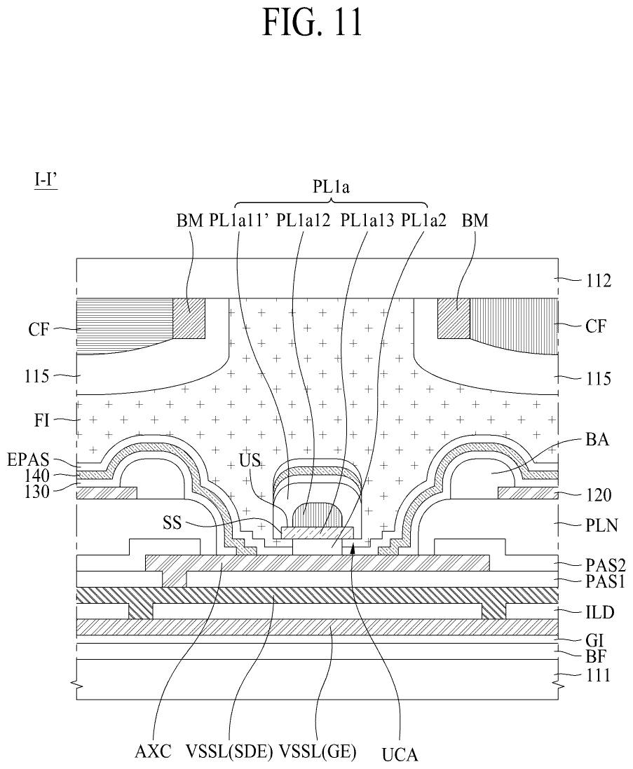

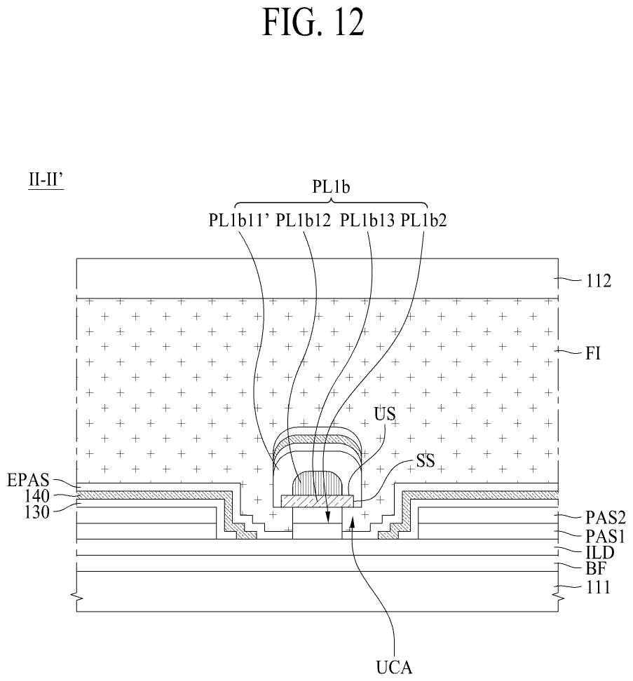

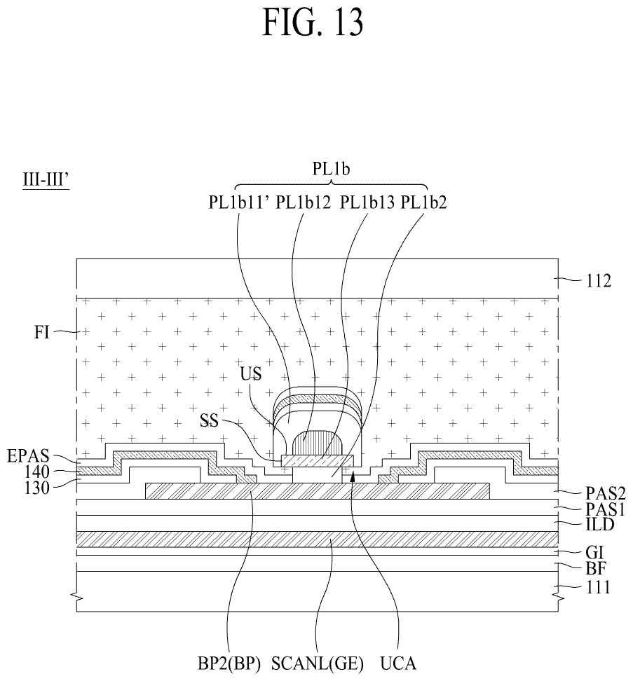

FIG. 11 is another cross-sectional view taken along line I-I′ shown in FIG. 4 according to the embodiment of the present disclosure. FIG. 12 is another cross-sectional view taken along line II-II′ shown in FIG. 4 according to the embodiment of the present disclosure. FIG. 13 is another cross-sectional view taken along line III-III′ shown in FIG. 4 according to the embodiment of the present disclosure. In FIGS. 11 to 13, the elements of at least one protruded line are modified in the transparent display panel 110 described with reference to FIGS. 1 to 10. In the following description, the same reference numerals will be given to the other same elements except for the modified elements, and their redundant description will be omitted or briefly described.

Referring to FIGS. 11 to 13 in conjunction with FIG. 4, the transparent display panel 110 according to the exemplary embodiment of the present disclosure may include at least one protruded line PL1 that includes a color filter material and a dummy electrode pattern.

At least one protruded line PL1 may be configured to be extended in different directions to cross between the first direction (or Y-axis direction) and the second direction (or X-axis direction) on the substrate 111. At least one protruded line PL1 on the substrate 111 may include a first protruded line portion PL1a overlapped with the non-transmissive area NTA and a second protruded line portion PL1b overlapped with the transmissive area TA.

Each of the first protruded line portion PL1a and the second protruded line portion PL1b includes (1-1)th pattern lines PL1a11′ and PL1b11′ made of the same material as that of the planarization layer PLN, (1-2)th pattern lines PL1a12 and PL1b12 made of a color filter material, dummy electrode patterns PL1a13 and PL1b13 made of a metal material, and second pattern lines PL1a2 and PL1b2 supporting the (1-1)th pattern lines PL1a11′ and PL1b11′, the (1-2)th pattern lines PL1a12 and PL1b12 and the dummy electrode patterns PL1a13 and PL1b13, configured by removing at least a portion of the first and second passivation layers PAS1 and PAS2 to have an undercut area UCA below the dummy electrode patterns PL1a13 and PL1b13.

The (1-1)th pattern lines PL1a11′ and PL1b11′ of each of the first protruded line portion PL1a and the second protruded line portion PL1b may be configured to cover upper surfaces US and side surfaces SS of the dummy electrode patterns PL1a13 and PL1b13. The (1-1)th pattern lines PL1a11′ and PL1b11′ may be formed to be more protruded than the dummy electrode patterns PL1a13 and PL1b13, thereby expanding an eaves structure on the second pattern lines PL1a2 and PL1b2.

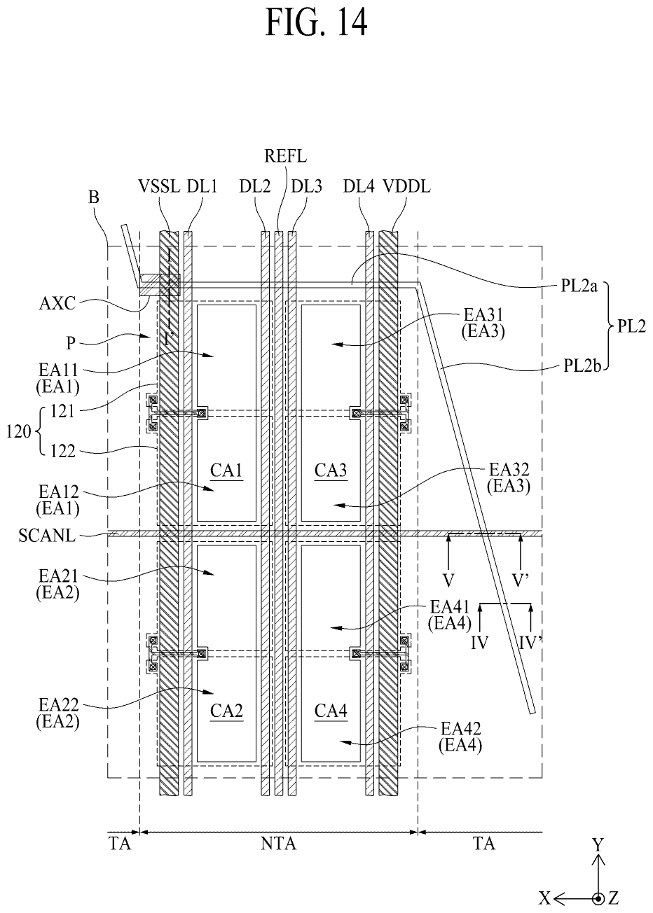

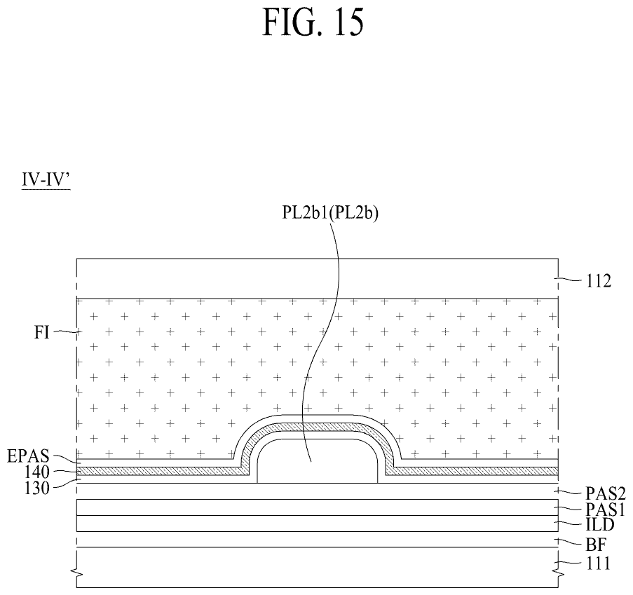

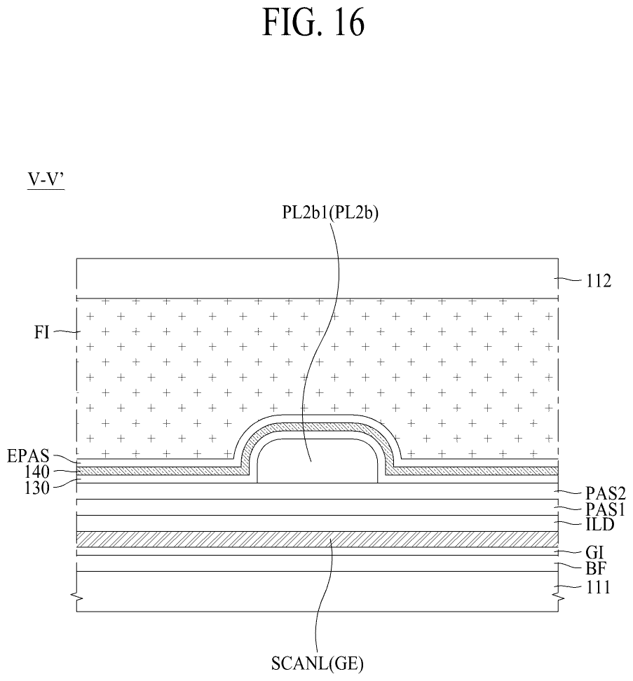

FIG. 14 is a view illustrating an area B shown in FIG. 3 according to another embodiment of the present disclosure. FIG. 15 is a cross-sectional view taken along line IV-IV′ shown in FIG. 14 according to another embodiment of the present disclosure. FIG. 16 is a cross-sectional view taken along line V-V′ shown in FIG. 14 according to another embodiment of the present disclosure. In FIGS. 14 to 16, the elements of at least one protruded line are modified in the transparent display panel 110 described with reference to FIGS. 1 to 13. In the following description, the same reference numerals will be given to the other same elements except for the modified elements, and their redundant description will be omitted or briefly described.

Referring to FIGS. 14 to 16, the transparent display panel 110 according to another embodiment of the present disclosure may further include at least one protruded line PL2 extended in different directions to cross between the first direction (or Y-axis direction) and the second direction (or X-axis direction) in the display area DA.

At least one protruded line PL2 may be disposed in the non-transmissive area NTA and the transmissive area TA of the display area DA. For example, at least one protruded line PL2 may include a first protruded line portion PL2a extended in the second direction (or X-axis direction) in the non-transmissive area NTA of the display area DA and a second protruded line portion PL2b extended in the third direction (or the diagonal direction) between the first direction (or Y-axis direction) and the second direction (or X-axis direction) in the transmissive area TA of the display area DA.

At least one protruded line PL2 may be configured to be protruded in the upward direction (or Z-axis direction) of the transparent display panel 110 (or the substrate). At least one protruded line PL2 may be made of the same material as that of the planarization layer PLN on the inorganic insulating layer (e.g., the passivation layer). For example, at least one protruded line PL2 may be formed in the form of a line pattern protruded in the upward direction (or Z-axis direction) of the transparent display panel 110 (or the substrate) by patterning the planarization layer PLN.

The first protruded line portion PL2a of at least one protruded line PL2 may be extended in the second direction (or X-axis direction) in the non-transmissive area NTA. The first protruded line portion PL2a may be configured to overlap at least a portion of the common power line VSSL in the non-transmissive area NTA. The auxiliary power contact portion AXC may be disposed at a portion where the first protruded line portion PL2a overlaps the common power line VSSL. The first protruded line portion PL2a may be configured such that an undercut area is formed only at a portion that overlaps the auxiliary power contact portion AXC but is not formed at a portion that does not overlap the auxiliary power contact portion AXC. The first protruded line portion PL2a may be disposed at an area that does not overlap the scan line SCANL (or the gate line) in the non-transmissive area NTA. For example, the first protruded line portions PL2a may be disposed to be spaced apart from each other with the scan line SCANL (or gate line) adjacent thereto in the first direction (or Y-axis direction), which is interposed therebetween, in the non-transmissive area NTA. For example, the plurality of subpixels SP1, SP2, SP3 and SP4 and the scan line SCANL (or the gate line) may be disposed between the first protruded line portions PL2a spaced apart from each other in the first direction (or Y-axis direction).

Referring to FIGS. 15 and 16, in the transmissive area TA on the substrate 111 according to another embodiment of the present disclosure, the second protruded line portion PL2b of at least one protruded line PL2 may be disposed. The second protruded line portion PL2b may be extended in the third direction (or the diagonal direction) between the first direction (or Y-axis direction) and the second direction (or X-axis direction) in the transmissive area TA. At least a portion of the second protruded line portion PL2b may be disposed to overlap at least one scan line SCANL (or the gate line) in the transmissive area TA. According to one embodiment of the present disclosure, most of the planarization layer PLN is removed from the transmissive area TA on the substrate 111 and the planarization layer is formed only in a partial area, whereby transparency of the transmissive area TA may be increased.

The second protruded line portion PL2b may be extended along the third direction (or the diagonal direction) in the transmissive area TA. The second protruded line portion PL2b may not overlap the scan line SCANL (or the gate line) in the transmissive area TA, as shown in FIG. 15. Also, the second protruded line portion PL2b may overlap the scan line SCANL (or the gate line) in the transmissive area TA, as shown in FIG. 16.

The second protruded line portion PL2b may include a first pattern line PL2b1 made of the same material as that of the planarization layer PLN on the second passivation layer PAS2.

The second protruded line portion PL2b according to another embodiment of the present disclosure may be disposed in a different area from the second protruded line portion PL1b described with reference to FIGS. 4 to 7 in the display area DA. For example, the second protruded line portion PL2b may serve to reduce a visibility deviation from the second protruded line portion PL1b having the undercut area UCA in the display area DA.

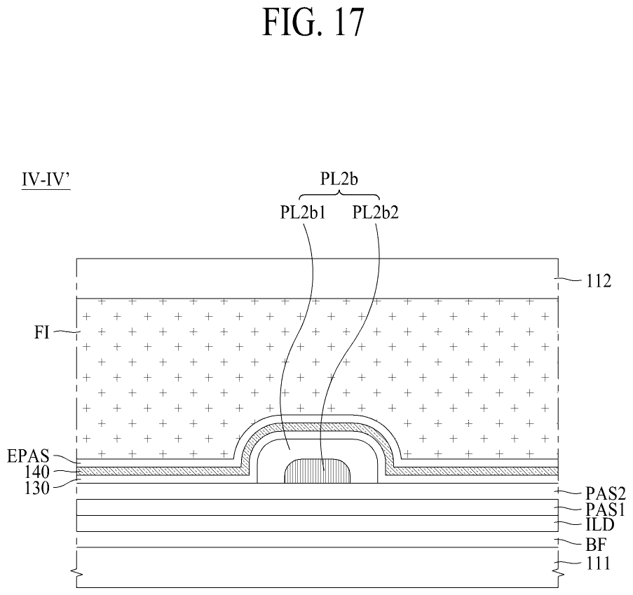

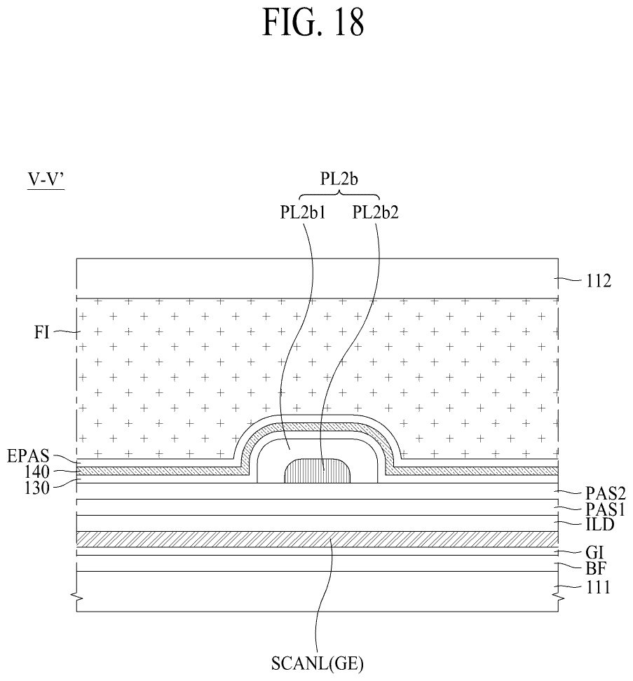

FIG. 17 is another cross-sectional view taken along line IV-IV′ shown in FIG. 14 according to another embodiment of the present disclosure. FIG. 18 is another cross-sectional view taken along line V-V′ shown in FIG. 14 according to another embodiment of the present disclosure. In FIGS. 17 and 18, the elements of at least one protruded line are modified in the transparent display panel 110 described with reference to FIGS. 14 to 16. In the following description, the same reference numerals will be given to the other same elements except for the modified elements, and their redundant description will be omitted or briefly described.

Referring to FIGS. 17 and 18 in conjunction with FIG. 14, at least one protruded line PL2 of the transparent display panel 110 according to another embodiment of the present disclosure may further include a color filter material. At least one protruded line PL2 may include a first protruded line portion PL2a extended in the second direction (or X-axis direction) in the non- transmissive area NTA of the display area DA and a second protruded line portion PL2b extended in the third direction (or the diagonal direction) between the first direction (or Y-axis direction) and the second direction (or X-axis direction) in the transmissive area TA of the display area DA.

At least one protruded line PL2 may be configured to be protruded in the upward direction (or Z-axis direction) of the transparent display panel 110 (or the substrate). At least one protruded line PL2 may include a color filter material and the planarization layer PLN on the inorganic insulating layer (e.g., the passivation layer).

Referring to FIGS. 17 and 18, the second protruded line portion PL2b of at least one protruded line PL2 may include a second pattern line PL2b2 made of a color filter material on the second passivation layer PAS2 and a first pattern line PL2b1 made of the same material as that of the planarization layer PLN while covering the second pattern line PL2b2. The color filter material of the second pattern line PL2b2 may include a blue color material.

The second protruded line portion PL2b according to another embodiment of the present disclosure may be disposed in a different area from the second protruded line portion PL1b described with reference to FIGS. 4 and 8 to 13 in the display area DA. For example, the second protruded line portion PL2b may serve to reduce a visibility deviation from the second protruded line portion PL1b having the undercut area UCA in the display area DA. Furthermore, the second protruded line portion PL2b according to another embodiment of the present disclosure may include a blue color filter material to be visible to be blueish in the transmissive area TA, whereby a yellowish problem that reduces visibility may be resolved.

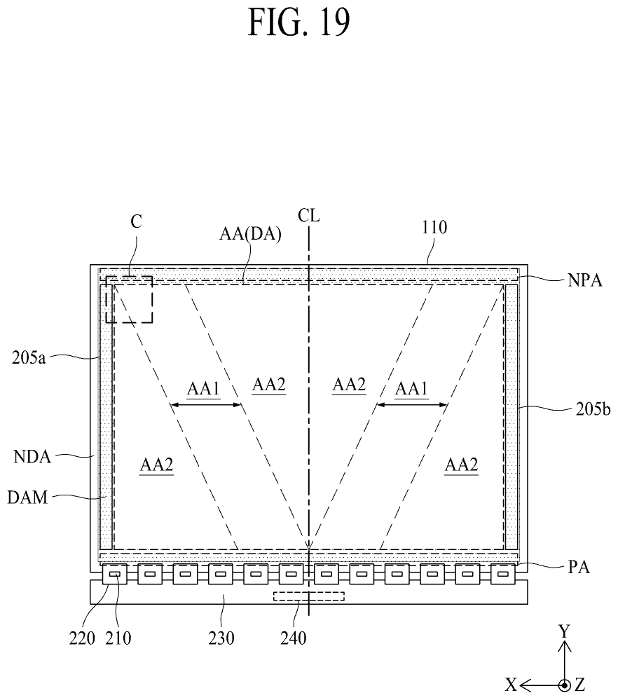

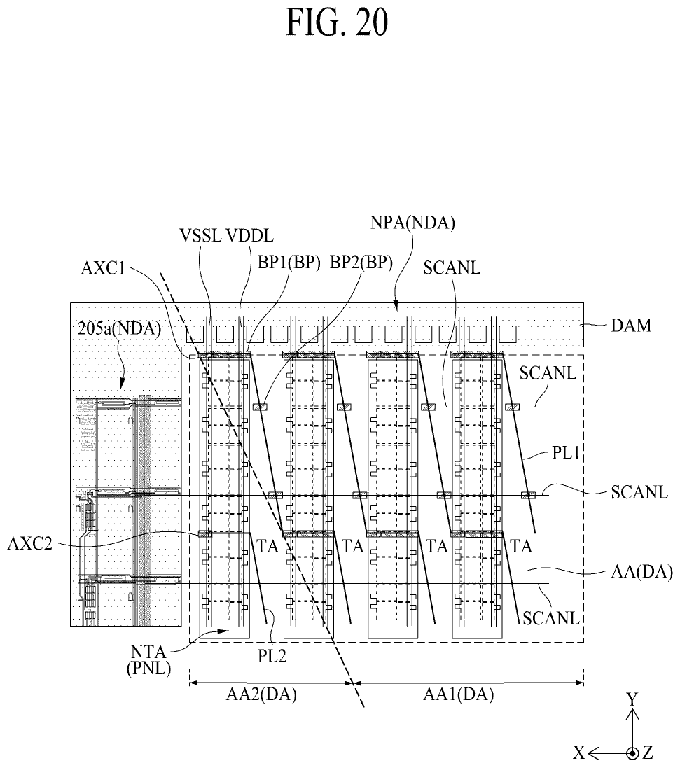

FIG. 19 is a cross-sectional view illustrating a transparent display apparatus according to another embodiment of the present disclosure. FIG. 20 is a view illustrating an area C shown in FIG. 19 according to another embodiment of the present disclosure.

Referring to FIGS. 19 and 20, the transparent display panel 110 according to another embodiment of the present disclosure may include a pixel area AA (or a display area DA) in which a plurality of pixels P consisting of a plurality of subpixels SP1, SP2, SP3 and SP4 and a transmissive area TA are disposed, and a non-display area NDA for not displaying an image.

The transparent display panel 110 according to another embodiment of the present disclosure may include at least one protruded line PL1 or PL2 extended in different directions to cross between the first direction (or Y-axis direction) and the second direction (or X-axis direction) in the pixel area AA (or the display area DA).

At least one protruded line PL1 or PL2 may include a portion extended in the second direction (or X-axis direction) in the non-transmissive area NTA of at least one pixel among a plurality of pixels arranged in the first direction (or Y-axis direction) in the pixel area AA and a portion extended in the third direction (or the diagonal direction) between the first direction and the second direction in the transmissive area TA of pixels adjacent to each other in the first direction (or Y-axis direction) among the plurality of pixels arranged in the first direction (or Y-axis direction) in the pixel area AA.

At least one protruded line PL1 or PL2 may be arranged in a plural number along a fourth direction (or a diagonal direction different from the third direction) different from the third direction (or the diagonal direction) between the first direction (or Y-axis direction) and the second direction (or X-axis direction) in the pixel area AA. The plurality of protruded lines PL1 and PL2 may be arranged to be spaced apart from each other in the second direction (or X-axis direction).

Each of the plurality of protruded lines PL1 and PL2 may have a portion extended in the second direction and a portion extended in the third direction, which may be extended in a stepwise shape along the fourth direction. For example, each of the plurality of protruded lines PL1 and PL2 may have the other end of the portion extended in the second direction and one end of the portion extended in the third direction, which are connected to each other, and the fourth direction may correspond to a virtual extension line connecting one end of the portion extended in the second direction with the other end of the portion extended in the third direction. The plurality of protruded lines PL1 and PL2 may be arranged symmetrically with respect to a central portion CL of the pixel area AA.

The pixel area AA may include a first pixel area AA1 and a second pixel area AA2, which are disposed on one side and the other side with respect to the central portion CL of the pixel area AA. For example, the first pixel area AA1 and the second pixel area AA2, which are disposed on one side (or a left side) with respect to the central portion CL of the pixel area AA, and the first pixel area AA1 and the second pixel area AA2, which are disposed on the other side (or a right side) with respect to the central portion CL of the pixel area AA, may be disposed symmetrically with each other.

The plurality of protruded lines PL1 and PL2 may include a plurality of first protruded lines PL1 disposed in the first pixel area AA1 and a plurality of second protruded lines PL2 disposed in the second pixel area AA2. The plurality of first protruded lines PL1 and the plurality of second protruded lines PL2 may be configured to have different shapes from each other. For example, the plurality of first protruded lines PL1 may be configured to have an undercut area UCA, and the plurality of second protruded lines PL2 may be configured such that an undercut area is not formed. For example, the plurality of first protruded lines PL1 may be configured in the same manner as at least one protruded line PL1 described with reference to FIGS. 4 to 13, and the plurality of second protruded lines PL2 may be configured in the same manner as at least one protruded line PL2 described with reference to FIGS. 14 to 18.

The first pixel area AA1 may be an area in which the plurality of first protruded lines PL1 are disposed to be extended from an upper edge of the pixel area AA to a lower edge of the pixel area AA, and the second pixel area AA2 is an area excluding the first pixel area AA1, and may be an area in which the plurality of second protruded lines PL2 are disposed.

The transparent display panel 110 may include a dam pattern DAM surrounding the pixel area AA. The dam pattern DAM may be configured in the form of a closed loop that surrounds the non-display area NDA around the pixel area AA. For example, the closed loop of the dam pattern DAM may be configured in the form of a rectangle. The pixel area AA surrounded by the dam pattern DAM may be a display area DA for displaying an image.

The transparent display panel 110 may include a plurality of gate drivers 205a and 205b. The transparent display panel 110 may include a source drive integrated circuit (hereinafter, referred to as “IC”) 210, a flexible film 220, a circuit board 230, and a timing controller 240.

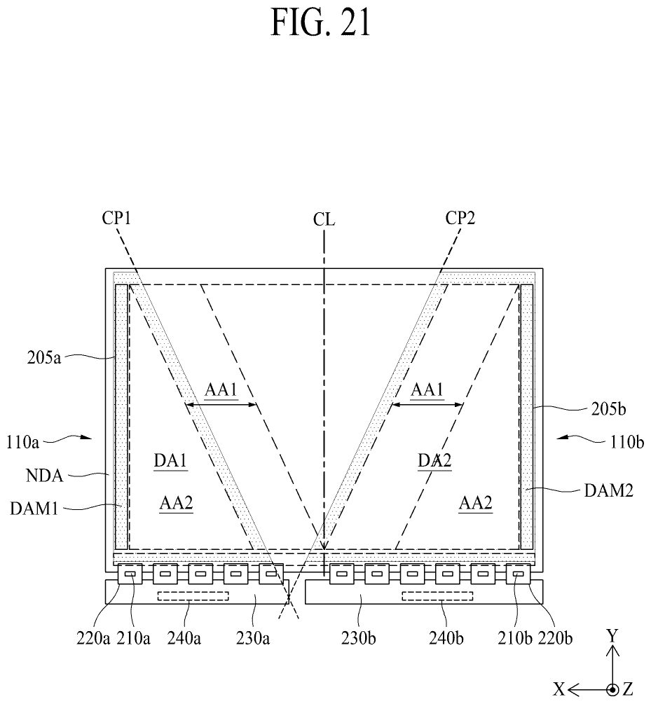

FIG. 21 is a view illustrating a transparent display apparatus according to another embodiment of the present disclosure.

Referring to FIG. 21, the transparent display panel 110 according to another embodiment of the present disclosure may include dam patterns DAM1 and DAM2 that divide the pixel area AA into at least two or more. The dam patterns DAM1 and DAM2 may be configured in the form of a closed loop that surrounds at least a portion of the non-display area NDA and the pixel area AA so that the pixel area AA may be divided into at least two or more. For example, the dam patterns DAM1 and DAM2 may include a first dam pattern DAM1 and a second dam pattern DAM2.

The first dam pattern DAM1 may be configured in the form of a closed loop that surrounds the second pixel area AA2 disposed on one side (or the left side) with respect to the central portion CL of the pixel area AA. The first dam pattern DAM1 may be configured in the form of a closed loop that surrounds a left boundary of the first pixel area AA1. For example, the closed loop of the first dam pattern DAM1 may be configured in the form of a triangle. The second pixel area AA2 surrounded by the first dam pattern DAM1 may be a first display area DA1 for displaying an image.

The second dam pattern DAM2 may be configured in the form of a closed loop that surrounds the first pixel area AA1 and the second pixel area AA2, which are disposed on the other side (or right side) with respect to the central portion CL of the pixel area AA. The second dam pattern DAM2 may be configured in the form of a closed loop that surrounds the left boundary of the first pixel area AA1. For example, the closed loop of the second dam pattern DAM2 may be configured in the form of a trapezoid. The first pixel area AA1 and the second pixel area AA2, which are surrounded by the second dam pattern DAM2, may be second display areas DA2 for displaying an image.

The transparent display panel 110 may include a plurality of gate drivers 205a and 205b. For example, the plurality of gate drivers 205a and 205b may include a first gate driver 205a and a second gate driver 205b. The first gate driver 205a may be disposed in the non-display area NDA positioned on the left side in the second direction (or X-axis direction), and the second gate driver 205b may be disposed in the non-display area NDA positioned on the right side in the second direction (or X-axis direction). For example, the first dam pattern DAM1 may be disposed to surround the first gate driver 205a and the second pixel area AA2 disposed on one side (or the left side) of the pixel area AA, and the second dam pattern DAM2 may be disposed to surround the second gate driver 205b and the first pixel area AA1 and the second pixel area AA2, which are disposed on the other side (or the right side) of the pixel area AA.

The transparent display panel 110 may include first and second source drive integrated circuits (hereinafter, referred to as “IC”) 210a and 210b, first and second flexible films 220a and 220b, first and second circuit boards 230a and 230b, and first and second timing controllers 240a and 240b.

The first source drive IC 210a, the first flexible film 220a, the first circuit board 230a and the first timing controller 240a may be connected to the first display area DA1 defined by the first dam pattern DAM1, and the second source drive IC 210b, the second flexible film 220b, the second circuit board 230b and the second timing controller 240b may be connected to the second display area DA2 defined by the second dam pattern DAM2.

A first cutting portion CP1 may be provided outside the first dam pattern DAM1, and a second cutting portion CP2 may be provided outside the second dam pattern DAM2. The first and second cutting portions CP1 and CP2 are portions at which the transparent display panel 110 may be separated or cut through a cutting device such as a laser or a wheel. For example, the first and second display areas DA1 and DA2 surrounded by the first and second dam patterns DAM1 and DAM2 may be a first transparent display panel 110a and a second transparent display panel 110b, respectively, which are independent of each other by being separated or cut by the first and second cutting portions CP1 and CP2.

The first and second dam patterns DAM1 and DAM2 may be non-display areas NDA (or bezel areas) of the first and second transparent display panels 110a and 110b, which are separated from each other. The first transparent display panel 110a may be configured in the form of a triangle, and the second transparent display panel 110b may be configured in the form of a trapezoid.

A transparent display apparatus according to one or more embodiments of the present disclosure will be described below.

A transparent display apparatus according to one or more embodiments of the present disclosure may include a substrate including a non-transmissive area including a light emission area in which a light emitting element is disposed and a transmissive area, at least one power line extended in a first direction in the non-transmissive area on the substrate, at least one gate line extended in a second direction transverse to the first direction to cross the non-transmissive area and the transmissive area on the substrate, and at least one protruded line extended in different directions to cross between the first direction and the second direction on the substrate.

According to one or more embodiments of the present disclosure, the at least one protruded line may be protruded in an upward direction of the substrate,

According to one or more embodiments of the present disclosure, the at least one protruded line may include at least one of an inorganic insulating material or an organic insulating material on the substrate.

According to one or more embodiments of the present disclosure, the at least one protruded line may be made of a same material as that of a planarization layer on at least one inorganic insulating layer on the substrate.

According to one or more embodiments of the present disclosure, the at least one protruded line may further include an undercut area configured by removing at least a portion of the at least one inorganic insulating layer below the planarization layer.

According to one or more embodiments of the present disclosure, the undercut area of the at least one protruded line may separate or disconnect an organic light emitting layer constituting the light emitting element.

According to one or more embodiments of the present disclosure, the at least one protruded line may further include a color filter material,

According to one or more embodiments of the present disclosure, the color filter material may include a blue color material.

According to one or more embodiments of the present disclosure, the color filter material of the at least one protruded line may be disposed on the at least one inorganic insulating layer, and may be covered by the planarization layer.

According to one or more embodiments of the present disclosure, the at least one protruded line may further include a dummy electrode pattern between the color filter material and the at least one inorganic insulating layer, and the color filter material of the at least one protruded line may be covered by the planarization layer and the dummy electrode pattern.

According to one or more embodiments of the present disclosure, the at least one protruded line may further include an undercut area configured by removing at least a portion of the at least one inorganic insulating layer below the dummy electrode pattern.

According to one or more embodiments of the present disclosure, an upper surface and side surfaces of the dummy electrode pattern of the at least one protruded line may be covered by the planarization layer.

According to one or more embodiments of the present disclosure, the at least one protruded line may include a first protruded line portion that overlaps the non-transmissive area, and a second protruded line portion that overlaps the transmissive area.

According to one or more embodiments of the present disclosure, the first protruded line portion may be extended in the second direction, and the second protruded line portion may be extended in a third direction between the first direction and the second direction.

According to one or more embodiments of the present disclosure, the first protruded line portion may overlap at least a portion of the at least one power line, and may not overlap the at least one gate line.

According to one or more embodiments of the present disclosure, the first protruded line portion may further include an undercut area configured by removing at least a portion of the at least one inorganic insulating layer below the planarization layer.

According to one or more embodiments of the present disclosure, the transparent display apparatus may further comprise an auxiliary power contact portion disposed in the non-transmissive area on the substrate, electrically connected to the at least one power line and overlapped with at least a portion of the first protruded line portion.

According to one or more embodiments of the present disclosure, a portion of the auxiliary power contact portion may be exposed by the undercut area of the first protruded line portion.

According to one or more embodiments of the present disclosure, the transparent display apparatus may further comprise at least one signal line disposed in the non-transmissive area on the substrate and extended in the first direction, and may further comprise a block pattern disposed between the first protruded line portion and the at least one signal line.

According to one or more embodiments of the present disclosure, the block pattern may be configured integrally with the auxiliary power contact portion or configured to be spaced apart from the auxiliary power contact portion.

According to one or more embodiments of the present disclosure, the second protruded line portion may not overlap the at least one power line, but may overlap at least a portion of the at least one gate line.

According to one or more embodiments of the present disclosure, the second protruded line portion may further include an undercut area configured by removing at least a portion of the at least one inorganic insulating layer below the planarization layer.

According to one or more embodiments of the present disclosure, the transparent display apparatus may further comprise a block pattern disposed at a portion where the second protruded line portion and the at least one gate line overlap each other.

According to one or more embodiments of the present disclosure, the substrate may include a pixel area in which a plurality of pixels consisting of a plurality of subpixels including the light emitting element disposed in the non-transmissive area and the transmissive area are disposed, and the at least one protruded line may include a first protruded line portion extended in the second direction in the non-transmissive area of at least one of the plurality of pixels arranged in the first direction in the pixel area, and a second protruded line portion extended from the first protruded line portion in a third direction between the first direction and the second direction in the transmissive area of pixels adjacent to each other in the first direction among the plurality of pixels arranged in the first direction in the pixel area.

According to one or more embodiments of the present disclosure, each subpixel may comprise a plurality of divided electrodes, and each divided electrode of the plurality of divided electrodes may correspond to a divided light emission area provided in each subpixel.

According to one or more embodiments of the present disclosure, the at least one protruded line may include a plurality of protruded lines arranged along a fourth direction different from the third direction between the first direction and the second direction in the pixel area.

According to one or more embodiments of the present disclosure, the plurality of protruded lines may be arranged to be spaced apart from each other in the second direction.

According to one or more embodiments of the present disclosure, the first protruded line portion and the second protruded line portion of the plurality of protruded lines may be extended in a stepwise shape along the fourth direction.

According to one or more embodiments of the present disclosure, the other end of the first protruded line portion and one end of the second protruded line portion may be connected to each other, and the fourth direction may correspond to a virtual extension line connecting one end of the first protruded line portion with the other end of the second protruded line portion.

According to one or more embodiments of the present disclosure, the plurality of protruded lines may be symmetrically arranged in the second direction with respect to a central portion of the pixel area.

According to one or more embodiments of the present disclosure, the pixel area may include a first pixel area and a second pixel area, which are respectively disposed on one side and the other side with respect to the central portion of the pixel area.

According to one or more embodiments of the present disclosure, the first and second pixel areas disposed on one side with respect to the central portion of the pixel area and the first and second pixel areas disposed on the other side with respect to the central portion of the pixel area may be symmetrical to each other.

According to one or more embodiments of the present disclosure, the plurality of protruded lines may include a plurality of first protruded lines disposed in the first pixel area, and a plurality of second protruded lines disposed in the second pixel area.

According to one or more embodiments of the present disclosure, the plurality of first protruded lines and the plurality of second protruded lines may be configured in different shapes.

According to one or more embodiments of the present disclosure, each of the plurality of first protruded lines may include a first pattern line made of the same material as that of the planarization layer on at least one inorganic insulating layer on the substrate, and a second pattern line supporting the first pattern line, configured by removing at least a portion of the at least one inorganic insulating layer to have an undercut area below the first pattern line, and the plurality of second protruded lines may include a first pattern line made of a same material as that of the planarization layer on at least one inorganic insulating layer on the substrate.

According to one or more embodiments of the present disclosure, the first pixel area may be an area in which the plurality of first protruded lines are disposed to be extended from an upper edge of the pixel area to a lower edge of the pixel area, and the second pixel area may be an area excluding the first pixel area.

According to one or more embodiments of the present disclosure, the transparent display apparatus may further comprise an opposite substrate disposed to face the substrate and disposed to correspond to the light emission area, including a color filter, and a connection member connecting the substrate with the opposite substrate.

According to one or more embodiments of the present disclosure, the substrate may include a display area and a non-display area adjacent to the display area, and the transparent display apparatus may further comprise a dam pattern between the substrate and the opposite substrate and disposed in the non-display area on the substrate.

According to one or more embodiments of the present disclosure, the transparent display apparatus may comprise a display panel including the substrate, the opposite substrate and the dam pattern, wherein the display panel may be configured in the form of at least one of a square, a triangle or a trapezoid.

According to one or more embodiments of the present disclosure, the dam pattern may be configured in the form of a closed loop that surrounds the non-display area on the substrate from a plan view.

According to one or more embodiments of the present disclosure, the closed loop of the dam pattern may be configured in the form of at least one of a square, a triangle or a trapezoid.

According to one or more embodiments of the present disclosure, at least a portion of the dam pattern may be disposed in parallel with the at least one protruded line.

According to one or more embodiments of the present disclosure, the at least one protruded line may be disposed to overlap the dam pattern.

According to one or more embodiments of the present disclosure, the opposite substrate may further include a plurality of upper passivation layers covering the color filter, and the upper passivation layers may be spaced apart from each other with the transmissive area interposed therebetween.

It will be apparent to those skilled in the art that various modifications and variations may be made in the apparatus of the present disclosure without departing from the scope of the disclosure. Thus, it is intended that the present disclosure cover the modifications and variations of this disclosure provided that within the scope of the claims and their equivalents.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A transparent display apparatus comprising:
a substrate including:
a non-transmissive area including a light emission area in which a light emitting element is disposed, and
a transmissive area;
at least one power line extended in a first direction in the non-transmissive area on the substrate;
at least one gate line extended in a second direction transverse to the first direction to cross the non-transmissive area and the transmissive area on the substrate; and
at least one protruded line extended in different directions to cross between the first direction and the second direction on the substrate.

2. The transparent display apparatus of claim 1, wherein the at least one protruded line is protruded in an upward direction of the substrate,

3. The transparent display apparatus of claim 1, wherein the at least one protruded line includes at least one of an inorganic insulating material or an organic insulating material on the substrate.

4. The transparent display apparatus of claim 1, wherein the at least one protruded line is made of a same material as that of a planarization layer on at least one inorganic insulating layer on the substrate.

5. The transparent display apparatus of claim 4, wherein the at least one protruded line further includes an undercut area configured by removing at least a portion of the at least one inorganic insulating layer below the planarization layer.

6. The transparent display apparatus of claim 5, wherein the undercut area of the at least one protruded line separates or disconnects an organic light emitting layer constituting the light emitting element.

7. The transparent display apparatus of claim 4, wherein the at least one protruded line further includes a color filter material,

8. The transparent display apparatus of claim 7, wherein the color filter material includes a blue color material.

9. The transparent display apparatus of claim 7, wherein the color filter material of the at least one protruded line is disposed on the at least one inorganic insulating layer, and is covered by the planarization layer.

10. The transparent display apparatus of claim 7, wherein the at least one protruded line further includes a dummy electrode pattern between the color filter material and the at least one inorganic insulating layer, and
wherein the color filter material of the at least one protruded line is covered by the planarization layer and the dummy electrode pattern.

11. The transparent display apparatus of claim 10, wherein the at least one protruded line further includes an undercut area configured by removing at least a portion of the at least one inorganic insulating layer below the dummy electrode pattern.

12. The transparent display apparatus of claim 11, wherein an upper surface and side surfaces of the dummy electrode pattern of the at least one protruded line is covered by the planarization layer.

13. The transparent display apparatus of claim 4, wherein the at least one protruded line includes:
a first protruded line portion that overlaps the non-transmissive area; and
a second protruded line portion that overlaps the transmissive area.

14. The transparent display apparatus of claim 13, wherein the first protruded line portion is extended in the second direction, and
wherein the second protruded line portion is extended in a third direction between the first direction and the second direction.

15. The transparent display apparatus of claim 14, wherein the first protruded line portion overlaps at least a portion of the at least one power line, and does not overlap the at least one gate line.

16. The transparent display apparatus of claim 15, wherein the first protruded line portion further includes an undercut area configured by removing at least a portion of the at least one inorganic insulating layer below the planarization layer.

17. The transparent display apparatus of claim 16, further comprising an auxiliary power contact portion disposed in the non-transmissive area on the substrate, electrically connected to the at least one power line and overlapped with at least a portion of the first protruded line portion.

18. The transparent display apparatus of claim 17, wherein a portion of the auxiliary power contact portion is exposed by the undercut area of the first protruded line portion.

19. The transparent display apparatus of claim 17, further comprising:
at least one signal line disposed in the non-transmissive area on the substrate and extended in the first direction; and
a block pattern disposed between the first protruded line portion and the at least one signal line.

20. The transparent display apparatus of claim 19, wherein the block pattern is configured integrally with the auxiliary power contact portion or configured to be spaced apart from the auxiliary power contact portion.

21. The transparent display apparatus of claim 14, wherein the second protruded line portion does not overlap the at least one power line, but overlaps at least a portion of the at least one gate line.

22. The transparent display apparatus of claim 21, wherein the second protruded line portion further includes an undercut area configured by removing at least a portion of the at least one inorganic insulating layer below the planarization layer.

23. The transparent display apparatus of claim 22, further comprising a block pattern disposed at a portion where the second protruded line portion and the at least one gate line overlap each other.

24. The transparent display apparatus of claim 1, wherein the substrate includes a pixel area in which a plurality of pixels consisting of a plurality of subpixels including the light emitting element disposed in the non-transmissive area and the transmissive area are disposed, and
wherein the at least one protruded line includes:
a first protruded line portion extended in the second direction in the non-transmissive area of at least one of the plurality of pixels arranged in the first direction in the pixel area; and
a second protruded line portion extended from the first protruded line portion in a third direction between the first direction and the second direction in the transmissive area of pixels adjacent to each other in the first direction among the plurality of pixels arranged in the first direction in the pixel area.

25. The transparent display apparatus of claim 24, wherein, each subpixel comprises a plurality of divided electrodes, and each divided electrode of the plurality of divided electrodes corresponds to a divided light emission area provided in each subpixel.

26. The transparent display apparatus of claim 24, wherein the at least one protruded line includes a plurality of protruded lines arranged along a fourth direction different from the third direction between the first direction and the second direction in the pixel area.

27. The transparent display apparatus of claim 26, wherein the plurality of protruded lines is arranged to be spaced apart from each other in the second direction.

28. The transparent display apparatus of claim 25, wherein the first protruded line portion and the second protruded line portion of the plurality of protruded lines are extended in a stepwise shape along the fourth direction.

29. The transparent display apparatus of claim 28, wherein the other end of the first protruded line portion and one end of the second protruded line portion are connected to each other, and
wherein the fourth direction corresponds to a virtual extension line connecting one end of the first protruded line portion with the other end of the second protruded line portion.

30. The transparent display apparatus of claim 26, wherein the plurality of protruded lines are symmetrically arranged in the second direction with respect to a central portion of the pixel area.

31. The transparent display apparatus of claim 30, wherein the pixel area includes a first pixel area and a second pixel area, which are respectively disposed on one side and the other side with respect to the central portion of the pixel area.

32. The transparent display apparatus of claim 31, wherein the first and second pixel areas disposed on one side with respect to the central portion of the pixel area and the first and second pixel areas disposed on the other side with respect to the central portion of the pixel area are symmetrical to each other.

33. The transparent display apparatus of claim 31, wherein the plurality of protruded lines include:
a plurality of first protruded lines disposed in the first pixel area; and
a plurality of second protruded lines disposed in the second pixel area.

34. The transparent display apparatus of claim 33, wherein the plurality of first protruded lines and the plurality of second protruded lines are configured in different shapes.

35. The transparent display apparatus of claim 33, wherein each of the plurality of first protruded lines includes:
a first pattern line made of the same material as that of a planarization layer on at least one inorganic insulating layer on the substrate; and
a second pattern line supporting the first pattern line, configured by removing at least a portion of the at least one inorganic insulating layer to have an undercut area below the first pattern line, and
wherein the plurality of second protruded lines includes a first pattern line made of a same material as that of the planarization layer on at least one inorganic insulating layer on the substrate.

36. The transparent display apparatus of claim 33, wherein the first pixel area is an area in which the plurality of first protruded lines is disposed to be extended from an upper edge of the pixel area to a lower edge of the pixel area, and
wherein the second pixel area is an area excluding the first pixel area.

37. The transparent display apparatus of claim 1, further comprising:
an opposite substrate disposed to face the substrate and disposed to correspond to the light emission area, including a color filter; and
a connection member connecting the substrate with the opposite substrate.

38. The transparent display apparatus of claim 37, wherein the substrate includes a display area and a non-display area adjacent to the display area,
wherein the transparent display apparatus further comprising a dam pattern between the substrate and the opposite substrate and disposed in the non-display area on the substrate.

39. The transparent display apparatus of claim 38, further comprising a display panel including the substrate, the opposite substrate and the dam pattern,
wherein the display panel is configured in the form of at least one of a square, a triangle or a trapezoid.

40. The transparent display apparatus of claim 39, wherein the dam pattern is configured in the form of a closed loop that surrounds the non-display area on the substrate from a plan view.

41. The transparent display apparatus of claim 40, wherein the closed loop of the dam pattern is configured in the form of at least one of a square, a triangle or a trapezoid.

42. The transparent display apparatus of claim 38, wherein at least a portion of the dam pattern is disposed in parallel with the at least one protruded line.

43. The transparent display apparatus of claim 42, wherein the at least one protruded line is disposed to overlap the dam pattern.

44. The transparent display apparatus of claim 37, wherein the opposite substrate further includes a plurality of upper passivation layers covering the color filter, and
wherein the upper passivation layers are spaced apart from each other with the transmissive area interposed therebetween.
